(19) United States
(12) Patent Application Publication
(10) Pub. No.: US 2007/0076832 A1
(43) Pub. Date: Apr. 5, 2007

(54) Semiconductor integrated circuit and correcting method of the same

(75) Inventor: Katsuki Matsudera, Kawasaki-shi (JP)

Correspondence Address: BANNER & WITCOFF, LTD., ATTORNEYS FOR RESERVE;ATTORNEYS FOR CLIENT NO. 000449, 001701, 1001 G STREET, N.W., 11TH FLOOR, WASHINGTON, DC, 20001-4597, US

(73) Assignee: Kabushiki Kaisha Toshiba, Minato-ku (JP)

(21) Appl. No.: 11/542,226

(22) Filed: Oct. 4, 2006

(30) Foreign Application Priority Data
Oct. 4, 2005 (JP) 2005-291472

(51) Int. Cl. H04L 7/00; H03D 3/24

(52) U.S. Cl. 375/371; 375/376

(57) ABSTRACT

According to an aspect of the embodiment, a semiconductor integrated circuit comprises: a multiphase clock generating circuit generating, in response to an input voltage, a first pair of clocks having reverse phases to each other and a second pair of clocks having phases which are substantially orthogonal to the phases of the first pair of clocks; a correcting circuit generating first and second output clock pairs by correcting a phase difference of the first and second clock pairs and duty cycles of the first and second clock pairs and a difference in phase between the first and second clock pairs; and a control circuit controlling the correcting circuit by detecting duty cycles of the first and second output clock pairs and a difference in phase between the first and second output clock pairs.

### CROSS-REFERENCE TO RELATED APPLICATIONS

This application is based upon and claims the benefit of priority from the prior Japanese Patent Application No. 2005-291472, filed on Oct. 4, 2005; the entire contents of which are incorporated herein by reference.

### BACKGROUND

1. Technical Field

The present invention relates to a semiconductor integrated circuit for generating a multiphase high-frequency clock.

2. Related Art

In recent years, a data transfer speed between semiconductor chips over a system is also increased with an increase in speeds of a computer, a game apparatus and a network apparatus. In a semiconductor memory such as a DRAM, particularly, a ratio of an increase in a speed of each input/output pin to an increase in a speed of an access cycle of a core (an increase in a frequency) has tended to be increased yearly. For this reason, the increase in the speed of the input/output circuit has been an important element for enhancing a performance of a high speed operation of a semiconductor memory. In order to increase a data rate of the input/output circuit, a high frequency clock having more phases than an external reference clock is also generated to implement an input/output having a high data rate by using a phase synchronizing loop (PLL) circuit (for example, see Kyu-hyoun Kim and others, “A 20 GB/s 256 Mb DRAM with an Inductorless Quadrature PLL and a Cascaded Pre-emphasis Transmitter”, International Solid State Component Circuit Conference (ISSCC) 2005 SESSION 25 DYNAMIC MEMORY 15.6, (U.S.A.), The Institute of Electrical and Electronics Engineers, Inc. (IEEE), Feb. 9, 2005).

In a CMOS circuit, generally, a duty cycle of a clock is influenced by a noise, a mismatch of transistor characteristics, a parasitic capacitance of the circuit and a mismatch of a parasitic resistance more easily when a transition time from a high level (hereinafter referred to as “H”) to “L” (hereinafter referred to as “L”) in a clock and from “L” to “H” is increased. In a PLL circuit, therefore, a voltage controlled oscillator (VCO) to be operated with a small amplitude and an amplifier circuit for amplifying a clock having a small amplitude which is output by the VCO to have a source voltage level is often a main cause of a deterioration in the duty cycle. The duty cycle (duty ratio) implies a ratio of “H” in a cycle of the clock and is usually maintained to be 50%.

The noise and the mismatch of the parasitic capacitances can be minimized by taking note of a symmetry of a circuit pattern in a design of a circuit and a layout. However, there is no method of reducing the mismatch of transistor characteristics other than an increase in a channel area of a transistor. By an increase in a channel area of the transistor, however, there is caused a bad effect such as an increase in a chip area, an increase in a consumed current and a deterioration in a high frequency characteristic. Due to these situations, an actual PLL circuit employs a circuit structure for correcting a duty cycle in an amplification from a clock having a small amplitude in a VCO to a CMOS clock in some cases.

In the case in which a multiphase high-frequency clock is used, however, a phase difference between clocks cannot be corrected by only a correction of the duty cycle. Since it is impossible to generate a multiphase high-frequency clock having a phase shifted evenly, accordingly, there is a possibility that a malfunction might be generated on an input/output circuit using the muitiphase high-frequency clock. Therefore, it is hard to maintain a reliability when a data rate of the input/output circuit is increased.

### SUMMARY

According to one aspect of the invention, there is provided a semiconductor integrated circuit includes: a multiphase clock generating circuit generating, in response to an input voltage, a first pair of clocks having reverse phases to each other and a second pair of clocks having phases which are substantially orthogonal to the phases of the first pair of clocks; a correcting circuit generating first and second output clockpairs by correcting a phase difference of the first and second clock pairs and duty cycles of the first and second clock pairs and a difference in phase between the first and second clock pairs; and a control circuit controlling the correcting circuit by detecting duty cycles of the first and second output clock pairs and a difference in phase between the first and second output clock pairs.

According to another aspect of the invention, there is provided a semiconductor integrated circuit includes: a multiphase clock generating circuit generating multiphase clocks including at least three clocks having different phases from each other in response to an input voltage; a correcting circuit correcting a difference in a phase between the clocks of the multiphase clocks and outputting multiphase output clocks including the same number of output clocks as the clocks in the multiphase clocks; and a control circuit detecting a difference in a phase between the output clocks having adjacent phases to each other in the multiphase output clocks and controlling the correcting circuit.

### BRIEF DESCRIPTION OF THE DRAWINGS

FIG. 1 is an exemplary block diagram showing an example of a structure of a semiconductor integrated circuit according to a first embodiment of the invention.

FIG. 2 is an exemplary time chart for explaining 4-phase clocks to be multiphase clocks generated by a PLL circuit according to the first embodiment.

FIG. 3 is an exemplary block diagram showing an example of schematic structures of a VCO, a correcting circuit and a control circuit according to the first embodiment.

FIG. 4 is an exemplary circuit diagram showing an example of a structure of the VCO according to the first embodiment.

FIG. 5 is an exemplary circuit diagram showing an example of a structure of a delay circuit included in the VCO according to the first embodiment.

FIG. 6 is an exemplary circuit diagram showing an example of a structure of an inverter included in the VCO according to the first embodiment.

FIG. 7 is an exemplary circuit diagram showing an example of a detailed structure of the control circuit according to the first embodiment.

FIG. 8 is an exemplary time chart for explaining operations of the correcting circuit and the control circuit according to the first embodiment.

FIG. 9 is an exemplary circuit diagram showing an example of a detailed structure of the correcting circuit according to the first embodiment.

FIG. 10 is an exemplary circuit diagram showing an example of a detailed structure of an output circuit according to the first embodiment.

FIG. 11 is an exemplary block diagram showing an example of schematic structures of a VCO, a correcting circuit and a control circuit according to various modifications of the first embodiment.

FIG. 12 is an exemplary circuit diagram showing an example of a detailed structure of the control circuit according to the variant of the first embodiment.

FIG. 13 is an exemplary circuit diagram showing an example of a detailed structure of the correcting circuit according to the variant of the first embodiment.

FIG. 14 is an exemplary circuit diagram showing an example of a detailed structure of a control circuit according to a second embodiment of the invention.

FIG. 15 is an exemplary block diagram showing an example of a schematic structure of a VCO, a correcting circuit and a control circuit according to a first variant of the second embodiment.

FIG. 16 is an exemplary circuit diagram showing an example of a structure of the VCO according to the first variant of the second embodiment.

FIG. 17(a) is an exemplary circuit diagram showing an example of a structure of a delay circuit included in the VCO according to the first variant of the second embodiment and FIG. 17(b) is an exemplary circuit diagram showing an example of a structure of an inverter included in the VCO according to the first variant of the second embodiment.

FIG. 18 is an exemplary circuit diagram showing an example of a detailed structure of the control circuit according to the first variant of the second embodiment.

FIG. 19 is an exemplary block diagram showing an example of schematic structures of a VCO, a correcting circuit and a control circuit according to a second variant of the second embodiment.

FIG. 20 is an exemplary circuit diagram showing an example of a structure of the VCO according to the second variant of the second embodiment.

FIG. 21 is an exemplary circuit diagram showing an example of a structure of a delay circuit included in an inverter according to the second variant of the second embodiment.

FIG. 22 is an exemplary circuit diagram showing an example of a detailed structure of the correcting circuit according to the second variant of the second embodiment.

FIG. 23 is an exemplary circuit diagram showing an example of a structure of an inverter included in the correcting circuit according to the second variant of the second embodiment.

FIG. 24 is an exemplary circuit diagram showing an example of a detailed structure of the control circuit according to the second variant of the second embodiment.

### DESCRIPTION OF THE EMBODIMENTS

Next, first and second embodiments according to the invention will be described with reference to the drawings. In the following description with reference to the drawings according to the first and second embodiments, the same or similar portions have the same or similar designations.

### First Embodiment

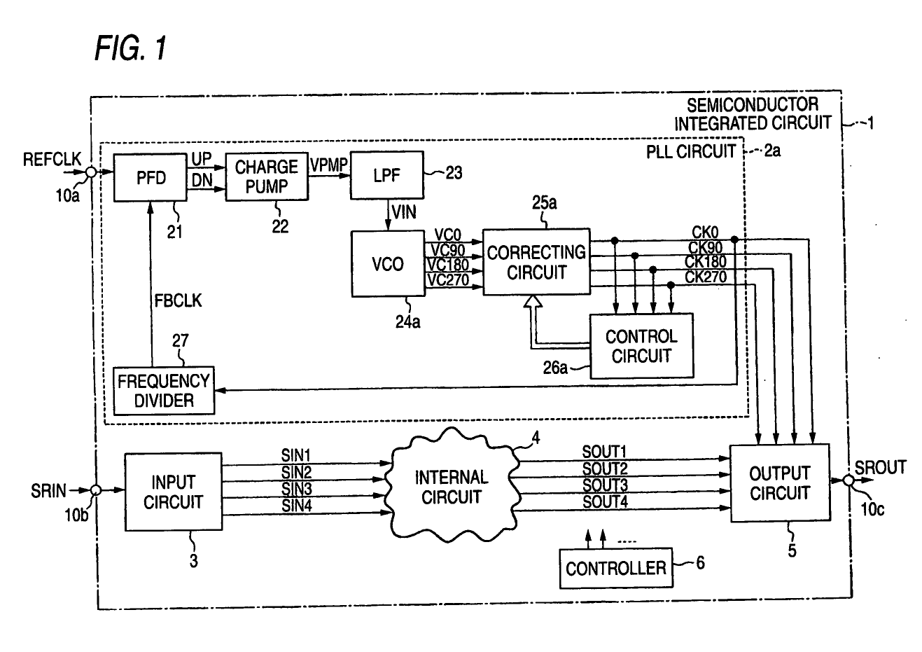

As shown in FIG. 1, a semiconductor integrated circuit 1 according to the first embodiment of the invention comprises a phase synchronizing loop (PLL) circuit 2a, an input circuit 3, an internal circuit 4, an output circuit 5 and a controller 6. The PLL circuit 2a includes a multiphase clock generating circuit (VCO) 24a for generating, in response to an input voltage VIN, a first pair of clocks VCO and VC180 having reverse phases to each other and a second pair of clocks VC90 and VC270 having phases which are orthogonal to the phases of the first pair of clocks VCO and VC180, a correcting circuit 25a for correcting a difference in the phase between the first pair of clocks VC0 and VC180 and the second pair of clocks VC90 and VC270 and duty cycles thereof and correcting the difference in the phase between the first pair of clocks VC0 and VC180 and the second pair of clocks VC90 and VC270, thereby generating a first pair of outputs CK0 and CK180 and a second pair of output clocks CK90 and CK270, and a control circuit 26a for detecting duty cycles of the first pair of output clocks CK0 and CK180 and the second pair of output clocks CK90 and CK270 and detecting a difference in a phase between the first pair of output clocks CK0 and CK180 and the second pair of output clocks CK9O and CK270, thereby controlling the correcting circuit 25a.

The first pair of clocks VC0 and VC180 is constituted by a first clock VC0 and a third clock VC180 having a reverse phase to the phase of the first clock VC0. The second pair of clocks VC90 and VC270 is constituted by a second clock VC90 and a fourth clock VC270 having a reverse phase to the phase of the second clock VC90. The first to fourth clocks VC0 to VC270 are multiphase clocks having small amplitudes in which the phases are shifted from each other by approximately 90 degrees. Assuming that the first clock VC0 is set to be a reference (0 degree), accordingly, the second clock VC90, the third clock VC180 and the fourth clock VC270 have phases of approximately 90 degrees, 180 degrees and 270 degrees, respectively.

Before a correcting operation is started, a slight error is made from 90 degrees in the difference in the phase among the first to fourth output clocks CK0 to CK270 which are output from the correcting circuit 25a due to, for example, a mismatch of transistor characteristics, parasitic capacitor of the transistor, and parasitic resistance of the transistor, in the VC0 24a and the correcting circuit 25a. After the correcting operation is started, the control circuit 26a detects the difference in the phase among the first to fourth output clocks CK0 to CK270 and feeds back the difference to the correcting circuit 25a. As a result, the correcting circuit 25a can correct and equalize the difference in the phase between the clocks to be 90 degrees.

Moreover, the PLL circuit 2a controls clock frequencies of the first to fourth output clocks CK0 to CK270 in response to a reference clock REFCLK supplied from an outside of the semiconductor integrated circuit 1. The PLL circuit 2a includes a phase frequency detector (PFD) 21, a charge pump 22, a low-pass filter (LPF) 23 and a frequency divider 27 in addition to the VC0 24a, the correcting circuit 25a and the control circuit 26a. The frequency divider 27 divides frequencies of the first to fourth output clocks CK0 to CK270, that is, multiplies cycles of the first to fourth output clocks CK0 to CK270 by an integer and outputs a feedback clock FBCLK to the PFD 21. Although the first output clock CK0 is input to the frequency divider 27 in the example shown in FIG. 1, it is also possible to employ a structure in which one of the second output clock CK90 to the fourth output clock CK270 is input to the frequency divider 27 in place of the first output clock CK0.

Furthermore, the PFD 21 compares phases and frequencies of the reference clock REFCLK input through a reference clock input terminal 10a from the outside of the semiconductor integrated circuit 1 and the feedback clock FBCLK with each other. If the frequency of the reference clock REFCLK is higher than that of the feedback clock FBCLK, the PFD 21 sets UP and DN signals to be “H” and “L” respectively. If the frequency of the reference clock REFCLK is lower than that of the feedback clock FBCLK, the PFD 21 sets the UP and DN signals to be “L” and “H” respectively.

The charge pump 22 increases a voltage level of an output voltage VPMP when the UP signal is “H” and the DN signal is “L”, and decreases the voltage level of the output voltage VPMP when the UP signal is “L” and the DN signal is “H”. The output voltage VPMP of the charge pump 22 is output as the input voltage VIN to the VC0 24a through the LPF 23.

The VC0 24a generates the multiphase clocks VC0 to VC270 having high frequencies when the voltage level of the input voltage VIN is high, and generates the multiphase clocks VC0 to VC270 having low frequencies when the voltage level of the input voltage VIN is low. Each of the multiphase clocks VC0 to VC270 generated by the VC0 24a is output as a clock having a smaller amplitude than a source voltage.

The correcting circuit 25a amplifies the amplitudes of the multiphase clocks VC0 to VC270 to the multiphase output clocks CK0 to CK270 obtained by a full amplification from a voltage level of a ground GND to that of a power supply Vcc. As a result, it is possible to generate the multiphase output clocks CK0 to CK270 which are suitable for a CMOS logic circuit such as the output circuit 5.

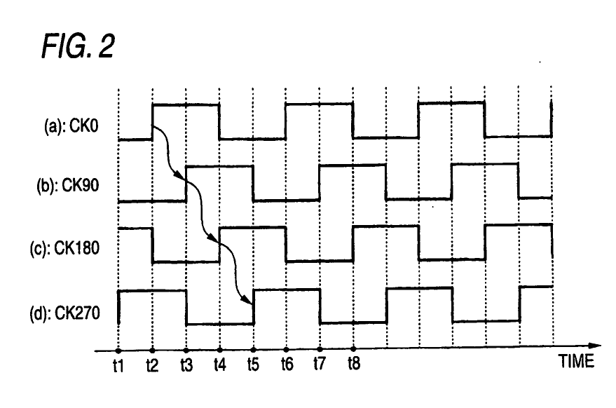

After the correcting operation is started, the first to fourth output clocks CK0 to CK270 generated by the PLL circuit 2a are changed into multiphase output clocks having phases shifted accurately from each other by 90 degrees as shown in FIG. 2. Assuming that the first output clock CK0 is set to be a reference (0 degree), accordingly, the phases of the second output clock CK90, the third output clock CK180 and the fourth output clock CK270 are set to be 90 degrees, 180 degrees and 270 degrees respectively.

Moreover, the input circuit 3 serial-parallel converts an input signal SRIN transferred serially from the outside into first to fourth input signals SIN1 to SIN4, for example. The internal circuit 4 receives the first to fourth input signals SIN1 to SIN4 and outputs first to fourth output signals SOUT1 to SOUT4. For the internal circuit 4, it is possible to use a memory circuit or a central processing unit (CPU), for example.

In the case in which the memory circuit is used as the internal circuit 4, the first to fourth input signals SIN1 to SIN4 are stored in the internal circuit 4. On the other hand, in the case in which the CPU is used as the internal circuit 4, the internal circuit 4 carries out various calculation processings for the first to fourth input signals SIN1 to SIN4.

Furthermore, the output circuit 5 carries out a parallel-serial conversion over the first to fourth output signals SOUT 1 to SOUT 4 sent from the internal circuit 4 by using the first to fourth output clocks CK0 to CK270 and serially transfers output data SROUT to the outside, for example. As a result, the output circuit 5 can transfer the output data SROUT at a data transfer speed which is four times as high as the clock frequencies of the first to fourth output clocks CK0 to CK270.

The controller 6 controls the input circuit 3, the internal circuit 4, the output circuit 5 and the PLL circuit 2a. In the case in which a memory circuit such as a DRAM is used as the internal circuit 4, the controller 6 receives a command such as a read command or a write command from the outside and carries out addressing to control the internal circuit 4. In the case in which a CPU is used as the internal circuit 4, the controller 6 receives a command from the CPU and transfers the command to the outside of the semiconductor integrated circuit 1.

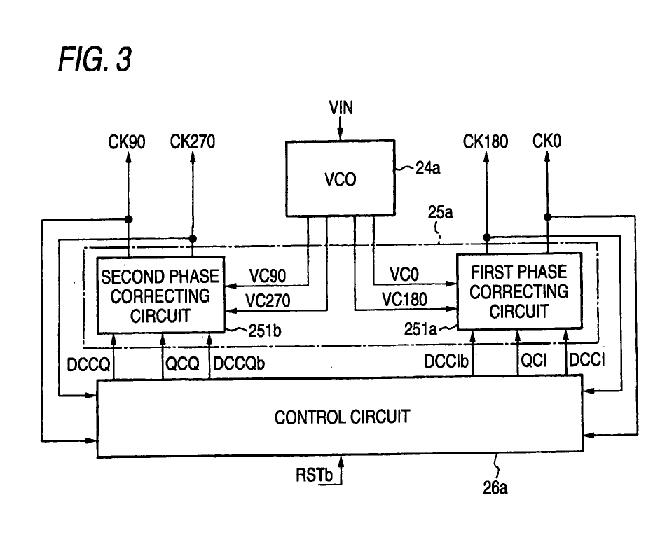

Furthermore, the correcting circuit 25a includes first and second phase correcting circuits 251a and 251b as shown in FIG. 3. The first phase correcting circuit 251a corrects a difference in a phase between the first pair of clocks VC0 and VC180 corresponding to a difference in an electric potential of a first control signal pair DCCI and DCCIb and controls an average delay of each of the first clocks VC0 and VC180 in response to a first phase difference control signal QCI, thereby generating the first output clockpair CK0 and CK180. The first clocks VC0 and VC180 have duty cycles corrected to be 50% by the first phase correcting circuit 251a and are output as the first output clock pair CK0 and CK180.

The second phase correcting circuit 251b corrects a difference in a phase between the second clocks VC90 and VC270 corresponding to a difference in an electric potential of a second pair of control signals DCCQ and DCCQb and controls an average delay of each of the second clocks VC90 and VC270 in response to a second phase difference control signal QCQ, thereby generating the second pair of output clocks CK90 and CK270. The second clocks VC90 and VC270 have duty cycles corrected to be 50% by the second phase correcting circuit 251b and are output as the second output clock pair CK90 and CK270.

Moreover, the control circuit 26a outputs the first pair of control signals DCCI and DCCIb having a difference in an electric potential which corresponds to a difference in a phase between the first output clock pair CK0 and CK180, outputs a second control signal pair DCCQ and DCGQb having a difference in an electric potential which corresponds to a difference in a phase between the second output clocks CK90 and CK270, and outputs a phase difference control signal pair QCI and QCQ having a difference in an electric potential which corresponds to a difference between the phase of the first output clock pair CK0 and CK180 and that of the second output clock pair CK90 and CK270. The phase difference control signal pair QCI and QCQ is constituted by a first phase difference control signal QCI and a second phase difference control signal QCQ and is used for correcting a difference between the phase of the first output clock pair CK0 and CK180 and that of the second output clock pair CK90 and CK270 to be 90 degrees.

In addition, the control circuit 26a increases the difference in an electric potential between the first control signals DCCI and DCCIb when the duty cycle of each of the first output clocks CK0 and CK180 is shifted from 50%, and maintains the difference in an electric potential between the first control signals DCCI and CDDIb when the duty cycle of each of the first output clocks CK0 and CK180 is set in a state of 50%.

Similarly, the control circuit 26a increases the difference in an electric potential between the second control signals DCCQ and DCCQb when the duty cycle of each of the second output clocks CK90 and CK270 is shifted from 50%, and maintains the difference in an electric potential between the second control signals DCCQ and DCCQb to be constant when the duty cycle of each of the second output clocks CK90 and CK270 is set in a state of 50%.

A correction start signal RSTb is supplied from the controller 6 shown in FIG. 1 to the control circuit 26a, for example, and an operation of the control circuit 26a is started in response to the correction start signal RSTb.

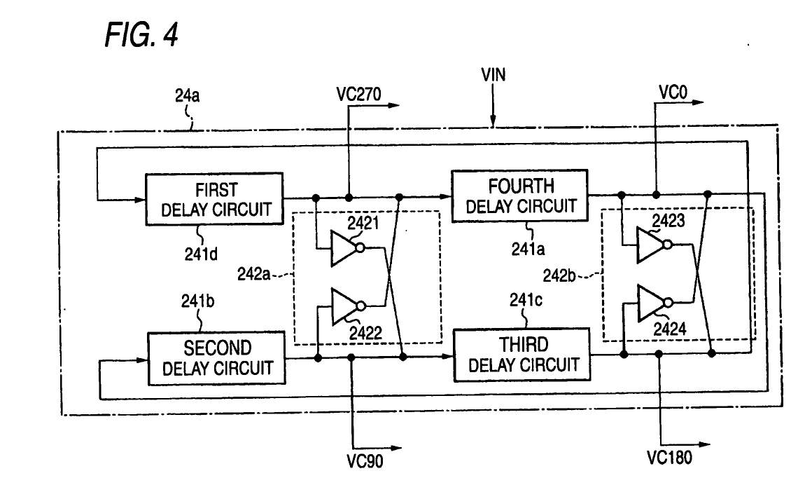

Furthermore, the VC0 24a includes first to fourth delay circuits 241a to 241d connected like a loop and first and second latch circuits 242a and 242b as shown in FIG. 4. The first to fourth delay circuits 241a to 241d and the first and second latch circuits 242a and 242b are operated by setting an input voltage VIN to be a source voltage (an operating voltage). Accordingly, each of delay times of the first to fourth delay circuits 241a to 241d is increased when an electric potential of the input voltage VIN is reduced, and is reduced when the electric potential of the input voltage VIN is raised.

The first delay circuit 241a delays the fourth clock VC270 and outputs the first clock VC0. The second delay circuit 241b delays the first clock VC0 and outputs the second clock VC90. The third delay circuit 241c delays the second clock VC90 and outputs the third clock VC180. The fourth delay circuit 241d delays the third clock VC180 and outputs the first clock VC0.

Propagation delays of the first to fourth delay circuits 241a to 241d are ideally equal to each other and depend on a voltage level of the input voltage VIN. As a result the VC0 24a has a frequency controlled by the input voltage VIN and outputs 4-phase clocks having phases shifted from each other by 90 degrees. However, a slight error is actually made from 90 degrees due to a mismatch of transistor characteristics.

The first and second latch circuits 242a and 242b arrange oscillating conditions of the VC0 24a. The first latch circuit 242a includes two inverters 2421 and 2422. Similarly, the second latch circuit 242b includes two inverters 2423 and 2424.

The first latch circuit 242a maintains the second clock VC90 and the fourth clock VC270 to have a complementary relationship, that is, maintains a phase difference to be 180 degrees. Similarly, the second latch circuit 242b maintains a phase difference between the first clock VC0 and the third clock VC180 to be 180 degrees.

In detail, the first delay circuit 241a includes CMOS inverters in two stages in total, that is, a CMOS inverter including a p-type channel MOS transistor (hereinafter referred to as a “pMOS transistor”) P₁ and an n-type channel MOS transistor (hereinafter referred to as an “nMOS transistor”) and a CMOS inverter including a pMOS transistor P₂ and an nMOS transistor N₂.

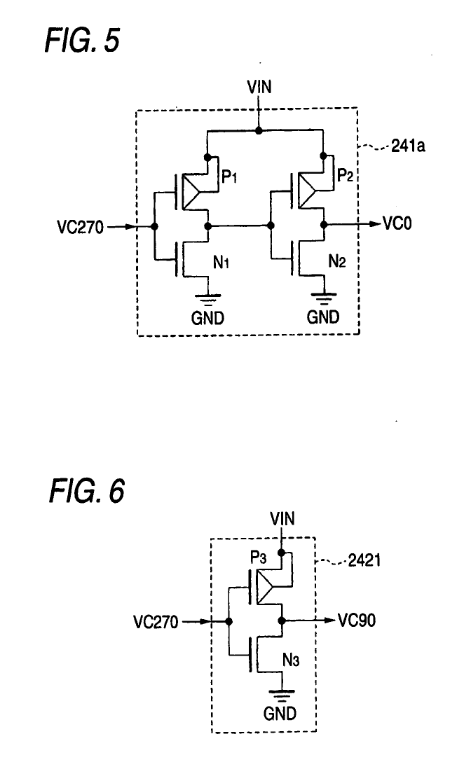

The input voltage VIN is applied to each of sources of the pMOS transistors P₁ and P₂. The second to fourth delay circuits 241b to 241d shown in FIG. 4 are constituted in the same manner as the first delay circuit 241a shown in FIG. 5. In all of the first to fourth delay circuits 241a to 241d, furthermore, sizes of the MOS transistors and wiring capacitances, parasitic capacitances and parasitic resistances of wirings are designed to be equal to each other in such a manner that all of the propagation delays are identical.

Moreover, the inverter 2421 shown in FIG. 4 includes a CMOS inverter constituted by a pMOS transistor P₃ and an nMOS transistor N₃ as shown in FIG. 6. The input voltage VIN is applied to a source of the pMOS transistor P₃. The inverters 2422, 2423 and 2424 shown in FIG. 4 are constituted in the same manner as the inverter 2421 shown in FIG. 5. In the inverters 2421, 2422, 2423 and 2424, furthermore, the sizes of the MOS transistors are selected to have proper values for the CMOS inverters in the first to fourth delay circuits 241a to 241d in such a manner that the VC0 24a carries out an oscillation.

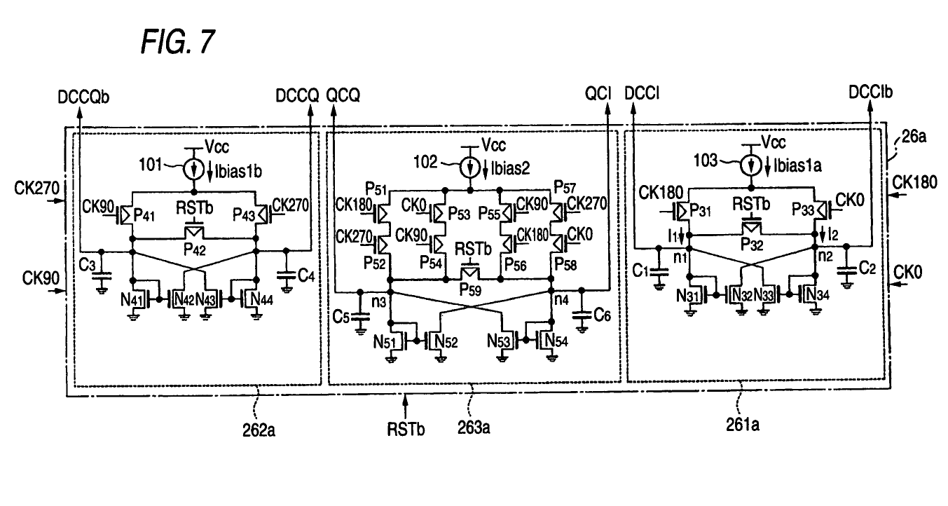

In addition, the control circuit 26a includes a first duty cycle detecting circuit 261a, a second duty cycle detecting circuit 262a and a phase difference detecting circuit 263a as shown in FIG. 7. The first duty cycle detecting circuit 261a converts a difference in the duty cycle between the first output clocks CK0 and CK180 into a mean current difference flowing in one cycle of the first output clock pair CK0 and CK180 by using a first reference current Ibias1a, and integrates the mean current difference and outputs the first pair of control signals DCCI and DCCIb.

The second duty cycle detecting circuit 262a converts a difference in the duty cycle between the second output clocks CK90 and CK270 into a mean current difference flowing in one cycle of the second output clock pair CK90 and CK270 by using a second reference current Ibias1b, and integrates the mean current difference and outputs the second pair of control signals DCCQ and DCCQb.

The phase difference detecting circuit 263a converts a phase difference between the phase of the first output clock pair CK0 and CK180 and the phase of the second output clock pair CK90 and CK270 into a mean current difference flowing in one cycle of the first output clock pair CK0 and CK180 and the second output clock pair CK90 and CK270 by using a third reference current Ibias2, and integrates the mean current difference and outputs the phase difference control signals QCI and QCQ.

Moreover, the first duty cycle detecting circuit 261a includes a constant current source 103, first to third PMOS transistors P₃₁ to P₃₃, first to fourth nMOS transistors N₃₁ to N₃₄, and first and second capacitors C₁ and C₂. The constant current source 103 has one of ends connected to a power supply Vcc and the other end connected to each of sources of the first and third PMOS transistors P₃₁ and P₃₃. The second pMOS transistor P₃₂ is connected between drains of the first and third pMOS transistors P₃₁ and P₃₃.

First to fourth nMOS transistors N₃₁ to N₃₄ are cross-coupled to each other and have sources connected to a ground GND. The first control signal DCCI is output from a node n₁ of a drain of the first pMOS transistor P₃₁ and each of drains of the first and third nMOS transistors N₃₁ and N₃₃. The second control signal DCCIb having a reverse phase (complementary) to the first control signal DCCI is output from a node n₂ of the drain of the third pMOS transistor P₃₃ and each of drains of the second and fourth nMOS transistors N₃₂ and N₃₄.

Moreover, the first and second nMOS transistors N₃₁ and N₃₂ constitute a current mirror circuit. In the case in which characteristics of the first and second nMOS transistors N₃₁ and N₃₂ are equal to each other, currents to flow to the first and second nMOS transistors N₃₁ and N₃₂ are equal to each other. Similarly, the third and fourth nMOS transistors N₃₃ and N₃₄ constitute a current mirror circuit. In the case in which characteristics of the third and fourth nMOS transistors N₃₃ and N₃₄ are equal to each other, currents to flow to the third and fourth nMOS transistors N₃₃ and N₃₄ are equal to each other.

The first capacitor C₁ is connected between the node n₁ and the ground GND. The second capacitor C₂ is connected between the node n₂ and the ground GND. The first capacitor C₁ integrates a current I₁ flowing to the node n₁. The second capacitor C₂ integrates a current I₂ flowing to the node n₂. For the first and second capacitors C₁ and C₂, is also possible to utilize a parasitic capacitance or a gate capacitance of an MOS transistor.

The constant current source 103 generates the constant current Ibias1a and supplies the same current Ibias1a to the first pMOS transistor P₃₁ and the third pMOS transistor P₃₃. In the case in which the duty cycles of the first output clocks CK0 and CK180 are equal to each other, mean currents of the currents I₂ and I₂ flowing to the nodes n₁ and n₂ are always almost equal to each other, that is, 0.5 X Ibias1a as long as the nMOS transistors N₃₁ to N₃₄ which are cross-coupled are operated in a saturation region.

In the case in which the first output clock CK0 is “H” and the third output clock CK180 is “L”, moreover, the constant current Ibias1a flows as the current I₁. On the other hand, when the first output clock CK0 is “L” and the third output clock CK180 is “H”, the constant current Ibias1a flows as the current I₂. The currents I₁ and I₂ are integrated into voltages by the first and second capacitors C₁ and C₂, respectively.

When the correction start signal RSTb is “L”, the second pMOS transistor P₃₂ is set in a conduction state. Therefore, electric potentials of the nodes n₁ and n₂ are equal to each other and a difference in an electric potential is not made over the first control signal pair DCCI and DCCIb. In the following description, a period before the correcting operation is started will be referred to as an “initial condition”.

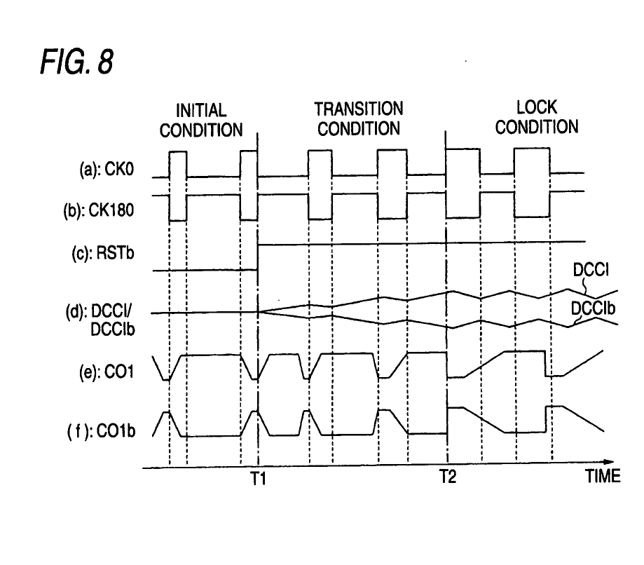

In a time chart shown in FIG. 8, the initial condition is set for a period before a time T1, the correction start signal RSTb is set to be “L” and voltages of the first control signals DCCI and DCCIb are equal to each other. In the initial condition, in the case in which the duty cycle of the first clock pair VC0 and VC180 is shifted from 50% or the case in which each of the transistors in the first phase correcting circuit 251a or the parasitic capacitance has an imbalance, an error is made over the duty cycles of the first output clock pair CK0 and CK180 from 50%. As an example, the duty cycle of the first output clock CK0 shown in FIG. 8(a) is approximately 25% and the duty cycle of the third output clock CK180 shown in FIG. 8(b) is approximately 75%.

On the other hand, when the correcting start signal RSTb is changed from “L” to “H”, the second pMOS transistor P₃₂ shown in FIG. 7 is brought into a non-conduction state. As a result, in the case in which the duty cycles of the first output clock CK0 and the third output clock CK180 are not equal to each other, a difference between the duty cycles appears as a difference in an electric potential between the first control signals DCCI and DCCIb.

The first pair of control signals DCCI and DCCIb are supplied to the first phase correcting circuit 251a shown in FIG. 3 and the duty cycles of the first output clocks CK0 and CK180 are corrected to be 50% corresponding to the difference in an electric potential between the first control signals DCCI and DCCIb. In the following description, a period before the duty cycle is corrected to be 50% since the start of the correcting operation will be referred to as a “transition condition”. A period after the duty cycle is corrected to be 50% will be referred to as a “lock condition”.

In the “lock condition”, all of the currents flowing to the nodes n₁ and n₂ and the currents flowing from the nodes n₁ and n₂ are equal to each other, that is, 0.5× Ibias1a. Therefore, the difference in an electric potential between the nodes n₁ and n₂ is maintained in such a level that the first phase correcting circuit 252a holds the duty cycles of the first output clocks CK0 and CK180 to be 50%.

The second duty cycle detecting circuit 262a is constituted in the same manner as the first duty cycle detecting circuit 261a and includes a constant current source 101, first to third pMOS transistors P₄₁ to P₄₃, first to fourth NMOS transistors N₄₁ to N₄₄, and first and second capacitors C₃ and C₄.

Furthermore, the phase difference detecting circuit 263a includes first to ninth pMOS transistors P₅₁ to P₅₉, first to fourth nMOS transistors N₅₁ to N₅₄, and first and second capacitor C₅ and C₆. The structures of the first to fourth nMOS transistors N₅₁ to N₅₄, and the first and second capacitors C₅ and C₆ are almost the same as those of the first and second duty cycle detecting circuits 261a and 262a.

In the phase difference detecting circuit 263a, four pMOS transistors P₅₅, P₅₆, P₅₇ and P₅₈ in which two pairs of two pMOS transistors connected in series are connected in parallel are used between the constant current source 102 and a node n₄ in which the first phase difference control signal QCI is generated. Similarly, four pMOS transistors P₅₁, P₅₂, P₅₃ and P₅₄ in which two pairs of two pMOS transistors connected in series are connected in parallel are used between the constant current source 102 and a node n₃ in which the second phase difference control signal QCQ is generated.

The third and fourth output clocks CK180 and CK270 are input to gates of the first and second pMOS transistors P₅₁ and P₅₂, respectively. The first and second output clocks CK0 and CK90 are input to gates of the third and fourth pMOS transistors P₅₃ and P₅₄, respectively.

The second and third output clocks CK90 and CK180 are input to gates of the fifth and sixth pMOS transistors P₅₅ and P₅₆, respectively. The fourth and first output clocks CK270 and CK0 are input to gates of the seventh and eighth pMOS transistors P₅₇ and P₅₈, respectively.

Accordingly, the current Ibias2 flows into the node n₄ in which the first phase difference control signal QCI is generated for a period in which the fourth output clock CK270 and the first output clock CK0 are “L” at the same time or a period in which the second output clock CK90 and the third output clock CK180 are “L” at the same time.

Similarly, the current Ibias2 flows into the node n₃ in which the second phase difference control signal QCQ is generated for a period in which the first output clock CK0 and the second output clock CK90 are “L” at the same time or a period in which the third output clock CK180 and the fourth output clock CK270 are “L” at the same time.

Therefore, the phase difference detecting circuit 263a increases a difference in an electric potential between the phase difference control signals QCI and QCQ when a sum of a difference in a phase between the fourth and first output clocks CK270 and CK0 and a difference in a phase between the second and third output clocks CK90 and CK180 is not equal to a sum of a difference in a phase between the first and second output clocks CK0 and CK90 and a difference in a phase between the third and fourth output clocks CK180 and CK270, and maintains the difference in an electric potential between the phase difference control signals QCI and QCQ to be constant when they are equal to each other.

More specifically, when the duty cycles of the first output clock pair CK0 and CK180 and the second output clock pair CK90 and CK270 are corrected to be 50%, the phase difference detecting circuit 263a increases the difference in an electric potential between the phase difference control signals QCI and QCQ when the difference in a phase between the first output clock pair CK0 and CK180 and the second output clock pair CK90 and CK270 is shifted from 90 degrees, and maintains the difference in an electric potential between the phase difference control signals QCI and QCQ to be constant when the phase difference between the first output clock pair CK0 and CK180 and the second output clock pair CK90 and CK270 is 90 degrees.

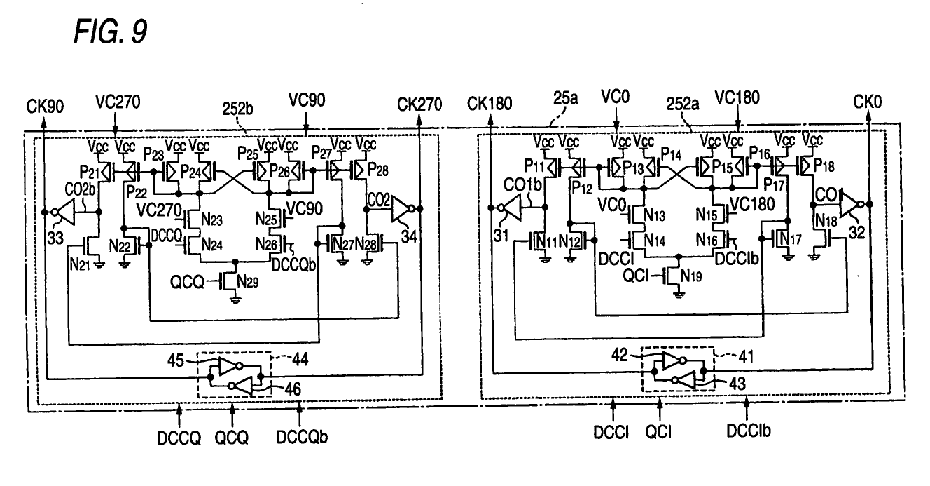

Furthermore, the first phase correcting circuit 252a includes first and second inverters 31 and 32, a latch circuit 41, first to eighth pMOS transistors P₁₁ to P₁₈, and first to ninth nMOS transistors N₁₁ to N₁₉ as shown in FIG. 9. Moreover, the first phase correcting circuit 252a corrects positions of falling and rising edges of the first output clock CK0 and the third output clock CK180 based on the difference in an electric potential between the first control signals DCCI and DCCIb.

Each of sources of the first to eighth pMOS transistors P₁₁ to P₁₈ is connected to a power supply Vcc. A gate of the first pMOS transistor P₁₁, a gate of the second pMOS transistor P₁₂, a gate and a drain of the third pMOS transistor P₁₃, a drain of the fourth pMOS transistor P₁₄, and a gate of the fifth pMOS transistor P₁₅ are connected mutually. A gate of the fourth pMOS transistor P₁₄, a drain of the fifth pMOS transistor P₁₅, a gate and a drain of the sixth pMOS transistor P₁₆, a gate of the seventh pMOS transistor P₁₇, and a gate of the eighth pMOS transistor P₁₈ are connected mutually.

The first nMOS transistor N₁₁ and the seventh nMOS transistor N₁₇ constitute a current mirror circuit. The second nMOS transistor N₁₂ and the eighth nMOS transistor N₁₈ constitute a current mirror circuit. The third and fourth nMOS transistors N₁₃ and N₁₄ are connected in series between a drain of the fourth pMOS transistor P₁₄ and that of the ninth nMOS transistor N₁₉. The fifth and sixth nMOS transistors N₁₅ and N₁₆ are connected in series between a drain of the fifth pMOS transistor P₁₅ and that of the ninth nMOS transistor N₁₉.

The third and fourth nMOS transistors N₁₃ and N₁₄ are connected in series between the drain of the fourth pMOS transistor P₁₄ and that of the ninth nMOS transistor N₁₉. The first output clock CK0 and the first control signal DCCI are supplied to gates of the third and fourth nMOS transistors N₁₃ and N₁₄, respectively.

The fifth and sixth nNOS transistors N₁₅ and N₁₆ are connected in series between the drain of the fifth pMOS transistor P₁₅ and that of the ninth nMOS transistor N₁₉. The third output clock CK180 and the second control signal DCCIb are supplied to gates of the fifth and sixth nMOS transistors N₁₅ and N₁₆, respectively.

As described above, the first duty cycle detecting circuit 261a shown in FIG. 7 increases a difference in an electric potential between the first control signals DCCI and DCCIb when the duty cycles of the first output clock CK0 and the third output clock CK180 are shifted from 50%.

The first phase correcting circuit 252a has the function of shifting edges of the first output clock CK0 and the third output clock CK180 corresponding to the difference in an electric potential between the first control signals DCCI and DCCIb. Accordingly, the first duty cycle detecting circuit 261a functions as a feedback circuit for setting the duty cycles of the first output clock CK0 and the third output clock CK180 to be 50% in a transition condition. As a result, the duty cycles of the first output clock CK0 and the third output clock CK180 are corrected to approximate to 50%.

In detail, as shown in FIGS. 8(e) and 8(f), when the electric potential of the second control signal DCCIb is raised, the inclinations of the falling edge of the signal CO1 and the rising edge of the signal CO1b become sharp. On the other hand, when the electric potential of the first control signal CDDI is decreased, the inclinations of the rising edge of the signal CO1 and that of the signal CO1b become gentle.

The first and second inverters 31 and 32 shown in FIG. 9 output inverted signals of the signals CO1b and the signal CO1 by setting an almost half level of the source voltage to be a threshold. The first and second inverters 31 and 32 invert the signals CO1b and CO1, and furthermore, generate the first pair of output clocks CK0 and CK180 which are amplified to the source voltage level. Moreover, the latch circuit 41 has such a structure that two inverters 42 and 43 are cross-coupled to each other and complementarily operates the first pair of output clocks CK0 and CK180.

Furthermore, the first phase difference control signal QCI is supplied to the gate of the ninth nMOS transistor N19. As a result, when the electric potential of the first phase difference control signal QCI is raised, a propagation delay is carried out quickly from the input of the first clock pair VC0 and VC180 to the output of the first output clock pair CK0 and CK180. On the other hand, when the electric potential of the first phase difference control signal QCI is reduced, the propagation delay is carried out slowly from the input of the first clock pair VC0 and VC180 to the output of the first output clock pair CK0 and CK180. Accordingly, it is possible to correct the phases of the first pair of output clocks CK0 and CK180, that is, positions of the rising and falling edges in response to the first phase difference control signal QCI.

As a result, the first phase correcting circuit 252a can correct the duty cycles of the first pair of clocks VC0 and VC180 based on the difference in an electric potential between the first control signals DCCI and DCCIb and can correct the rising and falling edges of the first clocks VC0 and VC180 at the same time, thereby generating the first output clock pair CK0 and CK180.

On the other hand, the second phase correcting circuit 252b is constituted in the same manner as the first phase correcting circuit 251a and includes first and second inverters 33 and 34, a latch circuit 44, first to eighth pMOS transistors P₂₁ to P₂₈, and first to ninth nMOS transistors N₂₁ to N₂₉. In the second phase correcting circuit 252b, when the electric potential of the second phase difference control signal QCQ is reduced, a propagation delay from the input of the second clock pair VC90 and VC270 to the output of the second output clock pair CK90 and CK270 is carried out slowly.

Accordingly, the correcting circuit 25a can generate the first output clock pair CK0 and CK180 and the second output clock pair CK90 and CK270 in which the duty cycles are 50% (a phase difference of 180 degrees). Furthermore, a period from the rising edge of the first output clock pair CK0 and CK180 to the rising edge of the second output clock pair CK90 and CK270 can be caused to be equal to a period from the rising edge of the second and fourth output clocks CK90 and CK270 to the rising edge of the first and third output clocks CK0 and CK180.

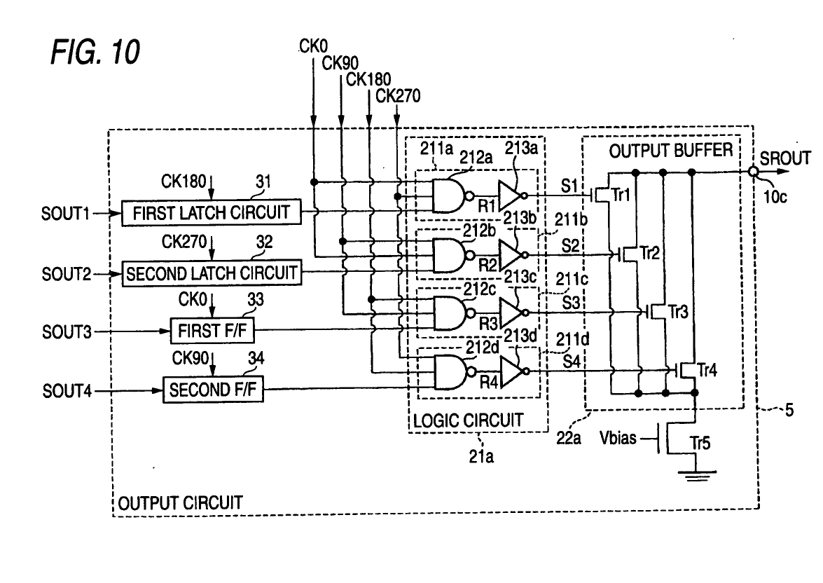

The output circuit 5 shown in FIG. 1 includes a first latch circuit 31, a second latch circuit 32, the first flip-flop (F/F) 33, the second F/F 34, a logic circuit 21a, an output buffer 22a and a current source transistor Tr5 as shown in FIG. FIG. 10, for example. The first latch circuit 31 causes the first output signal SOUT1 to pass at the rising edge of the third output clock CK180 and maintains an output when the third output clock CK180 is “L”. As a result, a first phase shift signal is generated. The second latch circuit 32 causes the second output signal SOUT2 to pass at the rising edge of the fourth output clock CK270 and maintains an output when the fourth output clock CK270 is “L”, thereby generating a second phase shift signal.

Moreover, the first F/F 33 holds the third output signal SOUT 3 at the rising edge of the first output clock CK0 and generates a third phase shift signal. The second F/F 34 holds the fourth output signal SOUT 4 at the rising edge of the second output clock CK90 and generates a fourth phase shift signal. As a result, the first to fourth phase shift signals have phases which are different from each other by 90 degrees, respectively.

Furthermore, the logic circuit 21a executes a logical calculation by combining one of the first to fourth phase shift signals with two of the first to fourth output clocks CK0 to CK270. The output buffer 22a generates the output data SROUT in response to the output of the logic circuit 21a. A constant voltage Vbias is applied to a gate of the current source transistor Tr5 and a constant current is supplied to the output buffer 22a.

The logic circuit 21a includes first to fourth AND circuits 211a to 211d. The first to fourth AND circuits 211a to 211d use two internal clocks having adjacent phases to each other in the first to fourth output clocks CK0 to CK270 for an AND calculation. As an example, the first AND circuit 211a carries out the AND calculation over the first output clock CK0, the fourth output clock CK270 and the first phase shift signal, thereby generating a first output control signal S1.

When the phase of the first output clock CK0 is set to be zero degree and that of the fourth output clock CK270 is set to be 270 degrees, the first output clock CK0 and the fourth output clock CK270 are brought into an “H” state at the same time in a specific timing. For a period in which the first output clock CK0 and the fourth output clock CK270 are brought into the “H” state at the same time, when the first phase shift signal is “H”, an “H” signal is generated from the first AND circuit 211a.

Moreover, each of the first to fourth AND circuits 211a to 211d is constituted as a CMOS circuit, for example. Accordingly, the first AND circuit 211a includes a first NAND circuit 212a and a first inverter 213a connected to the first NAND circuit 212a. Similarly, the second AND circuit 211b includes a second NAND circuit 212b and a second inverter 213b connected to the second NAND circuit 212b. The third AND circuit 211c includes a third NAND circuit 212c and a third inverter 213c connected to the third NAND circuit 212c. The third AND circuit 211d includes a third NAND circuit 212d and a third inverter 213d connected to the third NAND circuit 212d.

Furthermore, the first NAND circuit 212a carries out an NAND calculation over the first output clock CK0, the fourth output clock CK270 and the first phase shift signal. The first inverter 213a inverts an output signal R1 of the first NAND circuit 211a, thereby generating a first output control signal S1. The second NAND circuit 212b carries out the NAND calculation over the first output clock CK0, the second output clock CK90 and the second phase shift signal. The second inverter 213b inverts an output signal R2 of the second NAND circuit 212b, thereby generating a second output control signal S2.

The third NAND circuit 212c carries out the NAND calculation over the second output clock CK90, the third output clock CK180 and the third phase shift signal NAND. The third inverter 213c inverts an output signal R3 of the third NAND circuit 212c, thereby generating a third output control signal S3. The fourth NAND circuit 212d carries out the NAND calculation over the third output clock CK180, the fourth output clock CK270 and the fourth phase shift signal. The fourth inverter 213d inverts an output signal R4 of the fourth NAND circuit 212d, thereby generating a fourth output control signal S4.

On the other hand, the output buffer 22a is constituted as an open drain type, for example. More specifically, the output buffer 22a includes first to fourth output transistors Tr1 to Tr4 connected in parallel between an output terminal 10c and the current source transistor Tr5. An nMOS transistor can be used for each of the first to fourth output transistors Tr1 to Tr4 and the current source transistor Tr5, for example. The first to fourth output transistors Tr1 to Tr4 are brought into an ON state in response to the first to fourth output control signals S1 to S4, respectively. In an output of data, only one of the first to fourth output control signals S1 to S4 is brought into “H”. Therefore, only one of the first to fourth output transistors Tr1 to Tr4 is brought into the ON state. The output terminal 10c is connected to a terminal power supply through a terminal resistor (not shown) on the outside of the semiconductor integrated circuit 1 shown in FIG. 1.

According to the first embodiment of the invention, thus, the duty cycles of the two pairs of clocks can be corrected to be 50% and the phase differences between the two pairs of clocks can be corrected to be 90 degrees. After all, the operation is carried out for correcting the difference in a phase among the 4-phase clocks to be 90 degrees. Accordingly, it is possible to generate the 4-phase clocks CK0 to CK270 having the phases shifted accurately from each other by 90 degrees without using a clock having a higher frequency than the 4-phase clocks CK0 to CK270. As a result, it is possible to provide the semiconductor integrated circuit 1 capable of increasing the transfer speed of the output data SROUT to be four times as high as the frequencies of the first to fourth output clocks CK0 to CK270 while suppressing an increase in a clock frequency and a consumed power. As an example, when the frequency of each of the first to fourth output clocks CK0 to CK270 is set to be 400 [MHz] or 800 [MHz], the data transfer speeds (bit rates) of the semiconductor integrated circuit 1 are 1.6 [Gbps] or 3.2 [Gbps] respectively. Accordingly, it is possible to enhance the transfer speed of the output data SROUT while suppressing the increase in the clock frequency.

### Variant of First Embodiment

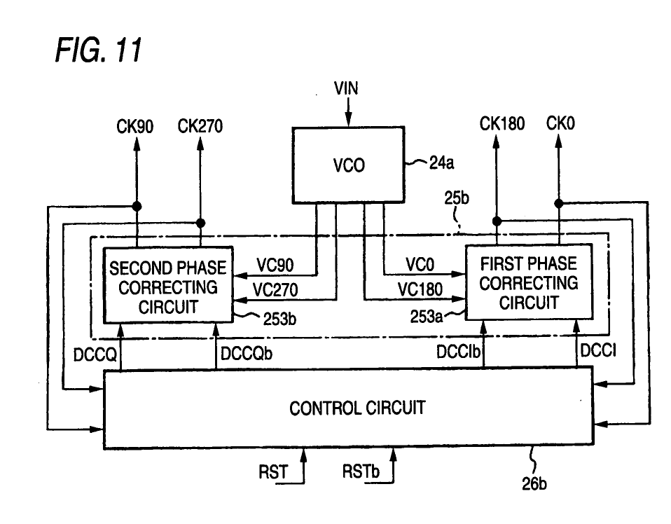

A semiconductor integrated circuit according to a variant of the first embodiment is different from that in FIG. 3 in that a control circuit 26b does not generate a pair of phase difference control signals QCI and QCQ as shown in FIG. 11. Moreover, FIG. 11 is different from FIG. 3 in that a first correcting start signal RSTb and a second correcting start signal RST having a reverse phase to the first correcting start signal RSTb are input to the control circuit 26b. A VC0 24a is constituted in the same manner as in FIG. 4.

While the control circuit 26a shown in FIG. 3 has the division into the first control signal pair DCCI and DCCIb and the second control signal pair DCCQ and DCCQb, and the phase difference control signal pair QCI and QCQ and feeds back them to the correcting circuit 25a, the control circuit 26b shown in FIG. 11 feeds back only the first control signal pair DCCI and DCCIb and the second control signal pair DCCQ and DCCQb to a correcting circuit 25b.

More specifically, the control circuit 26b corrects duty cycles of a first pair of output clocks CK0 and Ck18O depending on a difference in an electric potential between the first control signal pair DCCI and DCCIb, and furthermore, controls a mean electric potential of the first control signal pair DCCI and DCCIb, thereby correcting positions of both of rising and falling edges of the first output clock pair CK0 and CK180 (a mean delay).

Similarly, the control circuit 26b controls a mean electric potential of a second control signal pair DCCQ and DCCQb, thereby correcting positions of both of rising and falling edges of the second output clock pair CK90 and CK270 (a mean delay).

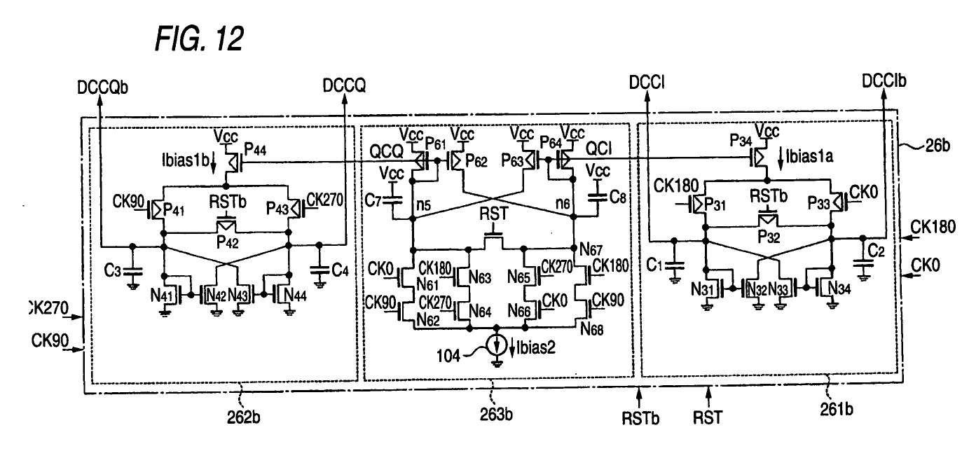

Moreover, the control circuit 26b includes a first duty cycle detecting circuit 261b, a second duty cycle detecting circuit 262b and a phase difference detecting circuit 263b as shown in FIG. 12. Structures of the first and second duty cycle detecting circuits 261b and 262b are the same as those in FIG. 7. In FIG. 12, however, a pMOS transistor P₄₄ and a pMOS transistor P₃₄ are used as the constant current source 101 and the constant current source 103 shown in FIG. 7, respectively. Reference currents Ibias1a and Ibias1b to be used in the first and second duty cycle detecting circuits 261b and 262b respectively are changed corresponding to electric potentials of a pair of phase difference control signals QCI and QCQ which are output from the phase difference detecting circuit 263b.

Furthermore, the phase difference detecting circuit 263b is obtained by a connection in which the pMOS transistors and the nMOS transistors in the phase difference detecting circuit 263a shown in FIG. 7 are constituted reversely. A difference in the electric potential between the phase difference control signals QCI and QCQ is increased when a sum of a difference in a phase between fourth and first output clocks CK270 and CK0 and a difference in a phase between second and third output clocks CK90 and CK180 is not equal to a sum of a difference in a phase between the first and second output clocks CK0 and CK90 and a difference in a phase between the third and fourth output clocks CK180 and CK270, and is maintained to be constant when they are equal to each other.

In detail, the phase difference detecting circuit 263b includes a constant current source 104, first to fourth pMOS transistors P₆₁ to P₆₄, first to eighth NMOS transistors N₆₁ to N₆₈, and first and second capacitors C₇ and C₈. In the phase difference detecting circuit 263b, four nMOS transistors N₆₅, N₆₆, N₆₇ and N₆₈ in which two pairs of two nMOS transistors connected in series are connected in parallel are used between a node n₆ at which the first phase difference control signal QCI is generated and the constant current source 104.

Similarly, four nMOS transistors N₆₁, N₆₂, N₆₃ and N₆₄ in which two pairs of two nMOS transistors connected in series are connected in parallel are used between a node n₅ at which the second phase difference control signal QCQ is generated and the constant current source 104.

The first and second output clocks CK0 and CK90 are input to gates of the first and second nMOS transistors N₆₁ and N₆₂, respectively. The third and fourth output clocks CK180 and CK270 are input to gates of the third and fourth nMOS transistors N₆₃ and N₆₄, respectively.

The fourth and first output clocks CK270 and CK0 are input to gates of the fifth and sixth nMOS transistors N₆₅ and N₆₆, respectively. The third and second output clocks CK180 and CK90 are input to gates of the seventh and eighth NMOS transistors N₆₇ and N₆₈, respectively.

Moreover, the first and second PMOS transistors P₆₁ and P₆₂ constitute a current mirror circuit. In the case in which characteristics of the first and second pMOS transistors P₆₁ and P₆₂ are equal to each other, currents to flow to the first and second pMOS transistors P₆₁ and P₆₂ are equal to each other. Similarly, the third and fourth pMOS transistors P₆₃ and P₆₄ constitute a current mirror circuit. In the case in which characteristics of the third and fourth pMOS transistors P₆₃ and P₆₄ are equal to each other, currents to flow to the third and fourth pMOS transistors P₆₃ and P₆₄ are equal to each other.

Accordingly, a current Ibias2 flows to the node n₆ in which the first phase difference control signal QCI is generated for a period in which the fourth output clock CK270 and the first output clock CK0 are “H” at the same time or a period in which the second output clock CK90 and the third output clock CK180 are “H” at the same time. Similarly, the current Ibias2 flows to the node n₅ in which the second phase difference control signal QCQ is generated for a period in which the first output clock CK0 and the second output clock CK90 are “H” at the same time or a period in which the third output clock CK180 and the fourth output clock CK270 are “H” at the same time. The current to flow to the node n₆ is integrated into a voltage by the capacitor C₈ and the current to flow to the node ns is integrated into a voltage by the capacitor C₇.

Therefore, the phase difference detecting circuit 263b increases a difference in an electric potential between the phase difference control signals QCI and QCQ when a sum of a difference in a phase between the fourth and first output clocks CK270 and CK0 and a difference in a phase between the second and third output clocks CK90 and CK180 is not equal to a sum of a difference in a phase between the first and second output clocks CK0 and CK90 and a difference in a phase between the third and fourth output clocks CK180 and CK270, and maintains the difference in an electric potential between the phase difference control signals QCI and QCQ to be constant when they are equal to each other.

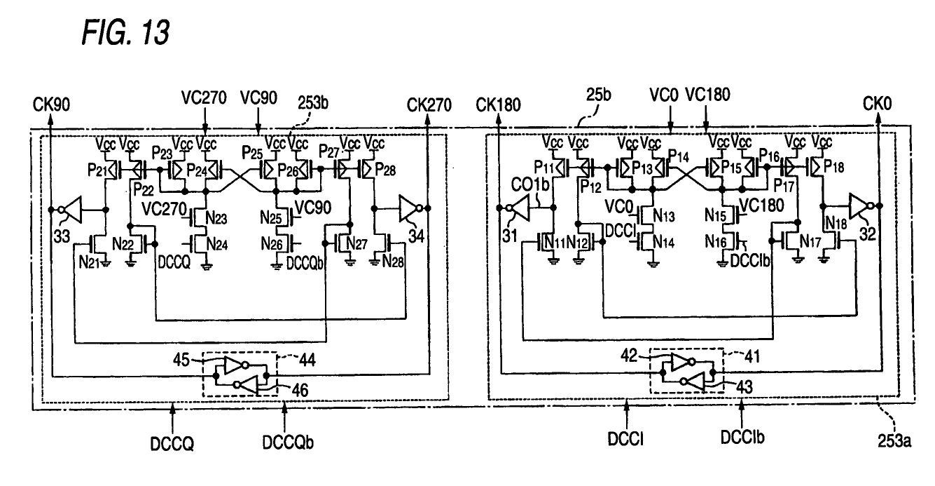

As shown in FIG. 13, furthermore, the correcting circuit 25b has such a structure as not to include the ninth nMOS transistor N₁₉ of the first phase correcting circuit 253a and the ninth nMOS transistor N₂₉ of the second phase correcting circuit 253b shown in FIG. 9.

According to the semiconductor integrated circuit in accordance with the variant of the first embodiment, thus, it is possible to feed back a difference in a phase between the first to fourth output clocks CK0 to CK270 and to set the difference in a phase between the clocks to be equal to 90 degrees in the same manner as in the first embodiment. Accordingly, it is possible to generate the 4-phase output clocks CK0 to CK270 having phases shifted accurately from each other by 90 degrees without using a clock having a higher frequency than the 4-phase output clocks CK0 to CK270. In the variant of the first embodiment, furthermore, it is possible to reduce the numbers of the MOS transistors and the signal wirings as compared with the first embodiment.

### Second Embodiment

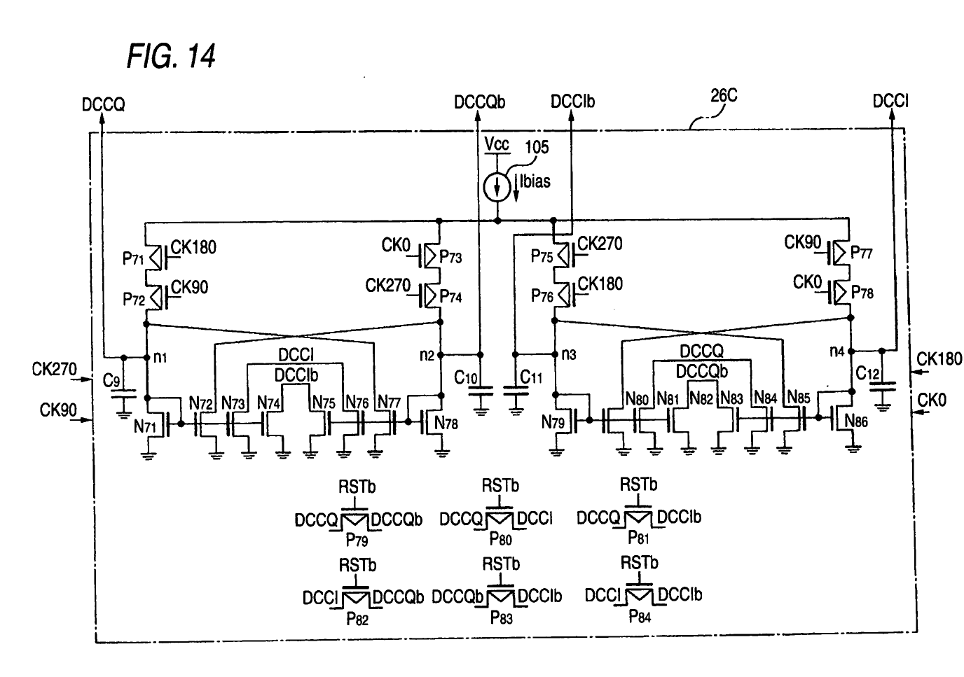

As shown in FIG. 14, a semiconductor integrated circuit according to a second embodiment of the invention is a control circuit 26c to be used together with the VC0 24a and the correcting circuit 25b shown in FIG. 11 and has such a structure as to detect a difference in a phase between any of first to fourth output clocks CK0 to CK270 which have adjacent phases to each other. The control circuit 26c receives the first to fourth output clocks CK0 to CK270 output from the correcting circuit 25b, and generates a first control signal pair DCCI and DCCIb having a difference in an electric potential corresponding to a difference in a phase between the fourth and first output clocks CK270 and CK0 and a difference in a phase between the second and third output clocks CK90 and CK180 and generates a second control signal pair DCCQ and DCCQb having a difference in an electric potential corresponding to a difference in a phase between the first and second output clocks CK0 and CK90 and a difference in a phase between the third and fourth output clocks CK180 and CK270.

The control circuit 26c shown in FIG. 14 includes a constant current source 105, first to fourteenth pMOS transistors P₇₁ to P₈₄, first to sixteenth nMOS transistors N₇₁ to N₈₆, and first to fourth capacitors C₉ to C₁₂. The first to sixteenth NMOS transistors N₇₁ to N₈₆ are cross-coupled to each other.

The first and second pMOS transistors P₇₁ and P₇₂ are connected in series between the constant current source 105 and an output node n₁ of the third control signal DCCQ. The third and fourth pMOS transistors P₇₃ and P₇₄ are connected in series between the constant current source 105 and an output node n₂ of the fourth control signal DCCQb. The fifth and sixth pMOS transistors P₇₅ and P₇₆ are connected in series between the constant current source 105 and an output node n₃ of the second control signal DCCIb. The seventh and eighth pMOS transistors P₇₇ and P₇₈ are connected in series between the constant current source 105 and an output node n₄ of the first control signal DCCI.

The third and second output clocks CK180 and CK90 are input to gates of the first and second pMOS transistors P₇₁ and P₇₂, respectively. The first and fourth output clocks CK0 and CK270 are input to gates of the third and fourth pMOS transistors P₇₃ and P₇₄, respectively. The fourth and third output clocks CK270 and CK180 are input to gates of the fifth and sixth pMOS transistors P₇₅ and P₇₆, respectively. The second and first output clocks CK90 and CK0 are input to gates of the seventh and eighth pMOS transistors P₇₇ and P₇₈, respectively.

Furthermore, the first to fourth nMOS transistors N₇₁ to N₇₄, the fifth to eighth nMOS transistors N₇₅ to N₇₈, the ninth to twelfth nMOS transistors N₇₉ to N₈₂, and the thirteenth to sixteenth nMOS transistors N₈₃ to N₈₆ constitute current mirror circuits, respectively. A part of signal wirings is not shown but the drains of the third and sixth nMOS transistors N₇₃ and N₇₆ are connected to the node n₄. The drains of the fourth and fifth nMOS transistors N₇₄ and N₇₅ are connected to the node n₃. The drains of the eleventh and fourteenth nMOS transistors N₈₁ and N₈₄ are connected to the node n₁. The drains of the twelfth and thirteenth nMOS transistors N₈₂ and N₈₃ are connected to the node n₂.

As long as each of the first to sixteenth nMOS transistors N₇₁ to N₈₆ is operated in a saturation state, accordingly, currents to flow from the constant current source 105 to a ground GND through the output nodes n₁ to n₄ are always almost equal to each other, that is, 0.25×Ibias.

Moreover, the ninth to fourteenth pMOS transistors P₇₉ to P₈₄ are set in a conduction state in an initial condition, and the electric potentials of the first control signal DCCI, the second control signal DCCIb, the third control signal DCCQ and the fourth control signal DCCQb are reset to be equipotential.

By a changeover to a transition condition from the initial condition, the ninth to fourteenth pMOS transistors P₇₉ to P₈₄ are brought into a non-conduction state. In the case in which an error is made over a difference in a phase among the first to fourthoutput clocks CK0 to CK270, a difference in an electric potential is made over the first control signal pair DDCI and DCCIb and the second control signal pair DCCQ and DCCQb.

The first and second pMOS transistors P₇₁ and P₇₂ are brought into a conduction state for a period in which both of the third and second output clocks CK180 and CK90 are “L”, for example, a period for a time of t2 to t3 shown in FIG. 2. Accordingly, a current flows from a power supply Vcc shown in FIG. 14 to the node n₁ for a period till a phase from a falling edge of the third output clock CK180 (a rising edge of the first output clock CK0) to a rising edge of the second output clock CK90.

As an example, when a difference in a phase from the rising edge of the first output clock CK0 to that of the second output clock CK90 is 72 degrees, the current flowing from the power supply Vcc into the node n₁ is 0.2×Ibias which is smaller than a current flowing to the ground GND (0.25×Ibias) so that the electric potential of the third control signal DCCQ is reduced.

When the difference in a phase from the rising edge of the first output clock CK0 to that of the second output clock CK90 is 90 degrees, moreover, the current flowing from the power supply Vcc to the node n₁ is 0.25×Ibias. Therefore, the current flowing into the node n₁ is balanced with a current flowing out so that the electric potential of the node n₁ (the third control signal DCCQ) is raised.

In the case in which the difference in a phase from the rising edge of the first output clock CK0 to that of the second output clock CK90 is 108 degrees which is greater than 90 degrees, the current flowing from the power supply Vcc into the node n₁ is 0.3×Ibias which is greater than the current flowing to the ground GND so that the electric potential of the node n₁ (the third control signal DCCQ) is raised.

Thus, the electric potential of the node n₁ (the third control signal DCCQ) is reduced when the difference in a phase from the rising edge of the first output clock CK0 to that of the second output clock CK90 is smaller than 90 degrees, and is raised when the difference is greater than 90 degrees.

Similarly, the third and fourth pMOS transistors P₇₃ and P₇₄ are brought into the conduction state for a period in which both of the first and fourth output clocks CK0 and CK270 are “L”, for example, a period for a time of t4 to t5 shown in FIG. 2. Accordingly, a current flows from the power supply Vcc shown in FIG. 14 into the node n₂ for a period till a phase from a rising edge of the third output clock CK180 to that of the fourth output clock CK270. As a result, the electric potential of the node n₂ (the fourth control signal DCCQb) is reduced when the difference in a phase from the rising edge of the third output clock CK180 to that of the fourth output clock CK270 is smaller than 90 degrees, and is raised when the difference is greater than 90 degrees.

Moreover, the fifth and sixth PMOS transistors P₇₅ and P₇₆ are brought into the conduction state for a period in which both of the fourth and third output clocks CK270 and CK180 are “L”, for example, a period for a time of t3 to t4 shown in FIG. 2. Accordingly, a current flows from the power supply Vcc shown in FIG. 14 into the node n₃ for a period till a phase from the rising edge of the second output clock CK90 to that of the third output clock CK180. As a result, the electric potential of the node n₃ (the second control signal DCCIb) is reduced when the difference in a phase between the rising edges of the second output clock CK90 and the third output clock CK180 is smaller than 90 degrees, and is raised when the difference is greater than 90 degrees.

The seventh and eighth pMOS transistors P_{77 and P}₇₈ are brought into the conduction state for a period in which both of the second and first output clocks CK90 and CK0 are “L”, for example, a period for a time of t1 to t2 shown in FIG. 2. Accordingly, a current flows from the power supply Vcc shown in FIG. 14 into the node n₄ for a period till a phase from the rising edge of the fourth output clock CK270 to that of the first output clock CK0. As a result, the electric potential of the node n₄ (the first control signal DCCI) is reduced when the difference in a phase between the rising edges of the fourth output clock CK270 and the first output clock CK0 is smaller than 90 degrees, and is raised when the difference is greater than 90 degrees.

By supplying the first control signal pair DCCI and DCCIb and the second control signal pair DCCQ and DCCQb to the correcting circuit 25b shown in FIG. 13, therefore, it is possible to generate the first to fourth output clocks CK0 to CK270 in which the difference in a phase among the first to fourth clocks VC0 to VC270 is corrected to be 90 degrees.

According to the second embodiment, thus, the control circuit 26c shown in FIG. 14 is used together with the VC0 24a and the correcting circuit 25b shown in FIG. 11. Consequently, it is possible to generate the 4-phase output clocks CK0 to CK270 having phases shifted accurately from each other by 90 degrees without using a clock having a higher frequency than the 4-phase output clocks CK0 to CK270. In the control circuit 26c shown in FIG. 14, furthermore, it is possible to reduce the number of elements of a circuit and a consumed current, and load gate capacities of the first to fourth output clocks CK0 to CK270 as compared with the control circuit 26b shown in FIG. 12.

### First Variant of Second Embodiment

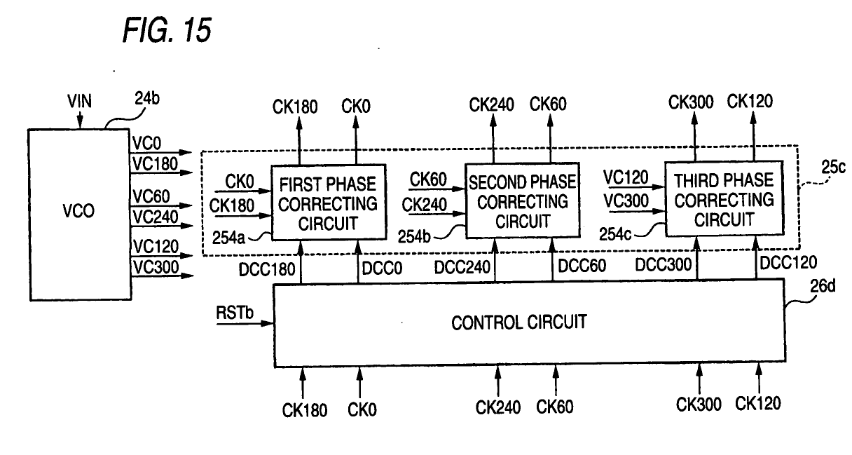

In a semiconductor integrated circuit according to a first variant of the second embodiment, a VC0 24b generates 6-phase clocks having phases shifted from each other by approximately 60 degrees, that is, a first clock VC0, a second clock VC60, a third clock VC120, a fourth clock VC180, a fifth clock 240 and a sixth clock VC300 as shown in FIG. 15. Assuming that the first clock VC0 is set to be a reference (zero degree), the phases of the second clock VC60, the third clock VC120, the fourth clock VC180, the fifth clock VC240 and the sixth clock VC300 are approximately 60 degrees, 120 degrees, 180 degrees, 240 degrees and 300 degrees, respectively. Each of the first to sixth clocks VC0 to VC300 has an amplitude which is smaller than a source voltage.

A correcting circuit 25c includes first to third phase correcting circuits 254a to 254c. In the first to sixth clocks VC0 to VC300, the first and fourth clocks VC0 and VC180 having phases in a complementary relationship are input as a first clock pair to a first phase correcting circuit 254a, the second and fifth clocks VC60 and VC240 are input as a second clock pair to a second phase correcting circuit 254b, and the third and sixth clocks VC120 and VC300 are input as a third clock pair to a third phase correcting circuit 254c.

Furthermore, the correcting circuit 25c amplifies the amplitudes of the first to sixth clocks VC0 to VC300, and furthermore, corrects the phase of each of the first to sixth clocks VC0 to VC300, thereby outputting first to sixth output clocks CK0 to CK300. 6-phase output clocks having phases shifted from each other by 60 degrees, that is, the first output clock CK0, the second output clock CK60, the third output clock CK120, the fourth output clock CK180, the fifth output clock CK240 and the sixth output clock CK300 are generated.

A control circuit 26d detects a difference in the phase among the first to sixth output clocks CK0 to CK300, thereby controlling the correcting circuit 25c. More specifically, the control circuit 26d outputs a first control signal pair DCCO and DCC180 having a difference in an electric potential corresponding to a difference in a phase between the first output clocks CK0 and CK180, outputs a second control signal pair DCC60 and DCC240 having a difference in an electric potential corresponding to a difference in a phase between the second output clocks CK60 and CK240, and outputs a third control signal pair DCC120 and DCC300 having a difference in an electric potential corresponding to a difference in a phase between the third output clocks CK120 and CK300.

Moreover, the first phase correcting circuit 254a corrects a difference in a phase between the first clocks VC0 and VC180 corresponding to a difference in an electric potential between the first control signals DCCO and DCC180 and corrects positions of both of rising and falling edges of the first clock pair VC0 and VC180 (a mean delay) corresponding to a mean electric potential of the first control signal pair DCCO and DCC180, thereby generating the first output clock pair CK0 and CK180.

Similarly, the second phase correcting circuit 254b corrects a difference in a phase between the second clocks VC60 and VC240 corresponding to a difference in an electric potential between the second control signals DCC60 and DCC240 and corrects positions of both of rising and falling edges of the second clock pair VC60 and VC240 (a mean delay) corresponding to a mean electric potential of the second control signal pair DCC60 and DCC240, thereby generating the second output clock pair CK60 and CK240.

The third phase correcting circuit 254c corrects a difference in a phase between the third clocks VC120 and VC300 corresponding to a difference in an electric potential between the third control signals DCC120 and DCC300 and corrects positions of both of rising and falling edges of the third clock pair VC120 and VC300 (a mean delay) corresponding to a mean electric potential of the third control signal pair DCC120 and DCC300, thereby generating the third output clock pair CK120 and CK300.

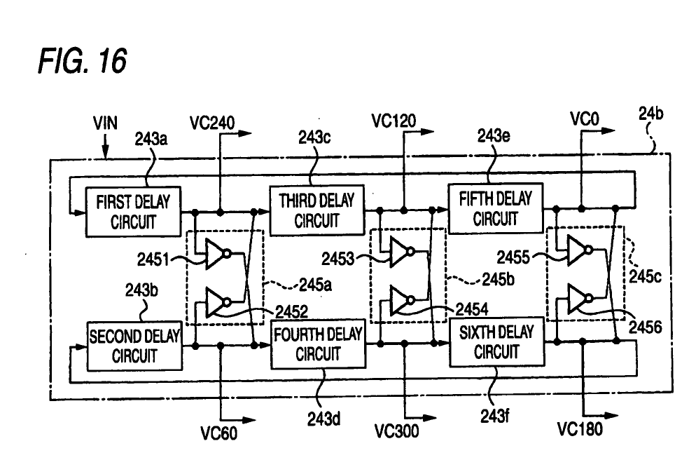

Furthermore, the VC0 24b includes first to sixth delay circuits 243a to 243f and first to third latch circuits 245a to 245c as shown in FIG. 16. The first to sixth delay circuits 243a to 243f and the first to third latch circuits 245a to 245c are operated by setting an input voltage VIN to be a source voltage (an operating voltage). Accordingly, each of delay times of the first to sixth delay circuits 243a to 243f is increased when an electric potential of the input voltage VIN is reduced, and is reduced when the electric potential of the input voltage VIN is raised.

The first delay circuit 243a delays the first clock VC0 and outputs the fifth clock VC240. The second delay circuit 243b delays the fourth clock VC180 and outputs the second clock VC60. The third delay circuit 243c delays the fifth clock VC240 and outputs the third clock VC120. The fourth delay circuit 243d delays the second clock VC60 and outputs the sixth clock VC300. The fifth delay circuit 243e delays the third clock VC120 and outputs the first clock VC0. The sixth delay circuit 243f delays the sixth clock VC300 and outputs the fourth clock VC180.

Moreover, the first latch circuit 245a includes two inverters 2451 and 2452. Similarly, the second latch circuit 245b includes two inverters 2453 and 2454. The third latch circuit 245c includes two inverters 2455 and 2456.

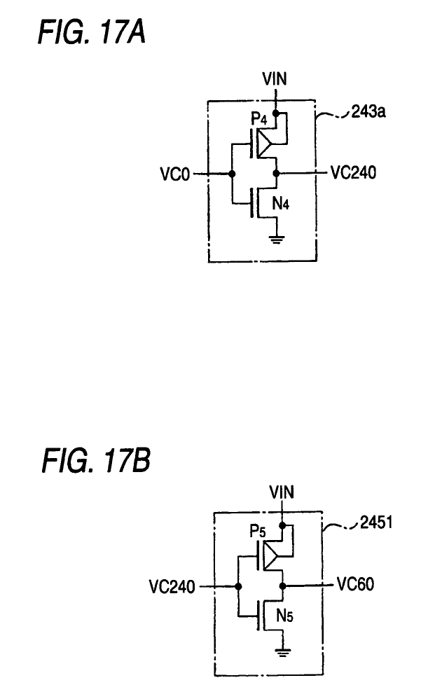

In detail, the first delay circuit 243a includes a CMOS inverter constituted by a pMOS transistor P₄ and an nMOS transistor N₄ as shown in FIG. 17(a). The input voltage VIN is applied to each of sources of pMOS transistors P₁ and P₂. The second to sixth delay circuits 243b to 243f shown in FIG. 16 are constituted in the same manner as the first delay circuit 243a shown in FIG. 17(a). The inverter 2451 shown in FIG. 16 includes a CMOS inverter constituted by a pMOS transistor P₅ and an NMOS transistor N₅ as shown in FIG. 17 (b).

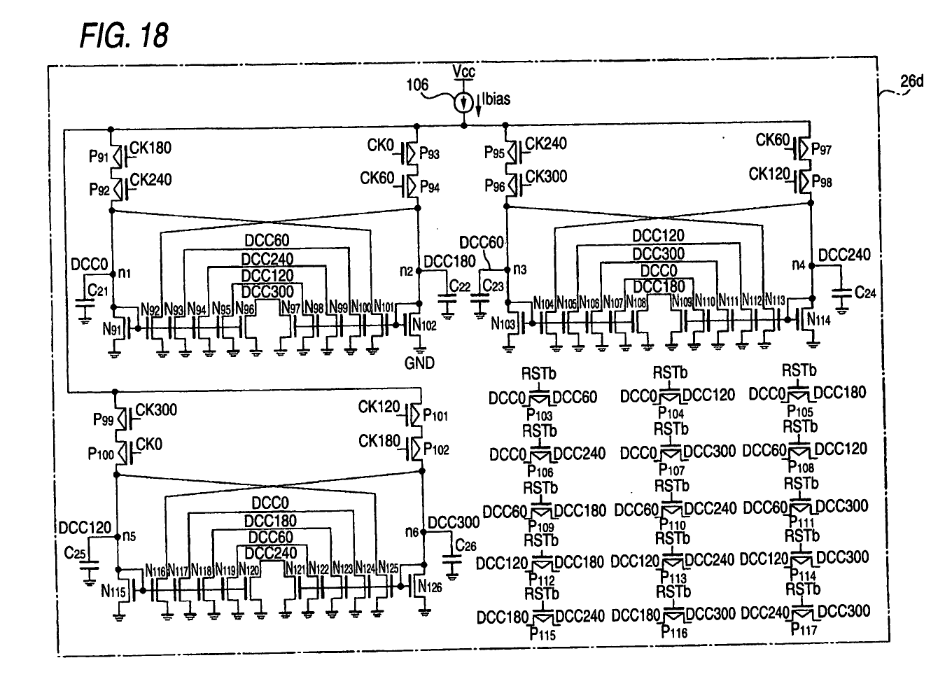

Furthermore, the control circuit 26d includes a constant current source 106, first to twenty-seventh pMOS transistors P₉₁ to P₁₁₇, first to thirty-sixth pMOS transistors N₉₁ to N₁₂₆, and first to sixth capacitors C₂₁ to C₂₆ as shown in FIG. 18. The first to thirty-sixth nMOS transistors N₉₁ to N₁₂₆ are cross-coupled to each other.

The first and second pMOS transistors P₉₁ and P₉₂ are connected in series between the constant current source 106 and an output node n₁ of the first control signal DCCO. The third and fourth PMOS transistors P₉₃ and P₉₄ are connected in series between the constant current source 106 and an output node n₂ of the fourth control signal DCC180. The fifth and sixth pMOS transistors P₉₅ and P₉₆ are connected in series between the constant current source 106 and an output node n₃ of the second control signal DCC60. The seventh and eighth pMOS transistors P₉₇ and P₉₈ are connected in series between the constant current source 106 and an output node n₄ of the fifth control signal DCC240. The ninth and tenth pMOS transistors P₉₉ and P₁₀₀ are connected in series between the constant current source 106 and an output node n₅ of the third control signal DCC120. The eleventh and twelfth pMOS transistors P₁₀₁ and P₁₀₂ are connected in series between the constant current source 106 and an output node n₆ of the sixth control signal DCC300.

The fourth and fifth output clocks CK180 and CK240 are input to gates of the first and second pMOS transistors P₉₁ and P₉₂, respectively. The first and second output clocks CK0 and CK60 are input to gates of the third and fourth pMOS transistors P₉₃ and P₉₄, respectively. The fifth and sixth output clocks CK240 and CK300 are input to gates of the fifth and sixth pMOS transistors P₉₅ and P₉₆, respectively. The second and third output clocks CK60 and CK120 are input to gates of the seventh and eighth pMOS transistors P₉₇ and P₉₈, respectively. The sixth and first output clocks CK300 and CK0 are input to gates of the ninth and tenth pMOS transistors P₉₉ and P₁₀₀, respectively. The third and fourth output clocks CK120 and CK180 are input to gates of the eleventh and twelfth pMOS transistors P₁₀₁ and P₁₀₂, respectively.

Furthermore, the first to sixth nMOS transistors N₉₁ to N₉₆, the seventh to twelfth nMOS transistors N₉₇ to N₁₀₂, the thirteenth to eighteenth nMOS transistors N₁₀₃ to N₁₀₈, the nineteenth to twenty-fourth nMOS transistors N₁₀₉ to N₁₁₄, the twenty-fifth to thirtieth nMOS transistors N₁₁₅ to N₁₂₀, and the thirty-first to thirty-sixth nMOS transistors N₁₂₁ to N₁₂₆ constitute current mirror circuits, respectively.

Drains of the seventeenth and twentieth nMOS transistors N₁₀₇ and N₁₁₀ and those of the twenty-seventh and thirty-fourth nMOS transistors N₁₁₇ and N₁₂₄ are connected to the node n₁, a part of signal wirings being omitted. Drains of the eighteenth and nineteenth nMOS transistors N₁₀₈ and N₁₀₉ and those of the twenty-eighth and thirty-third nMOS transistors N₁₁₈ and N₁₂₃ are connected to the node n₂.

Drains of the third and tenth nMOS transistors N₉₃ and N₁₀₀ and those of the twenty-ninth and thirty-second nMOS transistors N₁₁₉ and N₁₂₂ are connected to the node n₃. Drains of the fourth and ninth nMOS transistors N₉₄ and N₉₉ and those of the thirtieth and thirty-first nMOS transistors N₁₂₀ and N₁₂₁ are connected to the node n₄.

Drains of the fifth and eighth nMOS transistors N₉₅ and N₉₈ and those of the fifteenth and twenty-second NMOS transistors N₁₀₅ and N₁₁₂ are connected to the node ns. Drains of the sixth and seventh nMOS transistors N₉₆ and N₉₇ and those of the sixteenth and twenty-first nMOS transistors N₁₀₆ and N₁₁₁ are connected to the node n₆.

Moreover, the thirteenth to twenty-seventh PMOS transistors P₁₀₃ to P₁₁₇ are set in a conduction state in an initial condition, and the electric potentials of the first to fourth control signals DCC0 to DCC300 are reset to be equipotential.

By a changeover to a transition condition from the initial condition, the thirteenth to twenty-seventh pMOS transistors P₁₀₃ to P₁₁₇ are brought into a non-conduction state. In the case in which an error is made over a difference in a phase among the first to sixth output clocks CK0 to CK300, a difference in an electric potential is made over the first control signal pair DDC0 and DCC180, the second control signal pair DCC60 and DCC240, and the third control signal pair DCC120 and DCC300.

According to the first variant of the second embodiment, therefore, it is possible to feed back a difference in a phase between the first to sixth output clocks CK0 to CK300 and to set the difference in a phase between the clocks to be equal to 60 degrees. Accordingly, it is possible to generate the 6-phase output clocks CK0 to CK300 having phases shifted accurately from each other by 60 degrees without using a clock having a higher frequency than these clocks. Furthermore, it is possible to provide the semiconductor integrated circuit capable of increasing a transfer speed of output data SROUT to be six times as high as the frequencies of the first to sixth output clocks CK0 to CK300 while suppressing an increase in a clock frequency and a consumed power.

### Second Variant of Second Embodiment

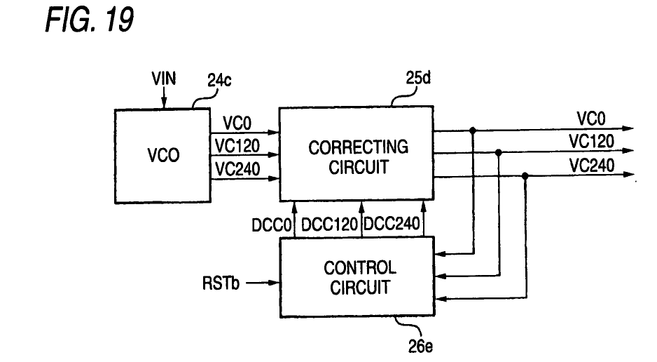

In a semiconductor integrated circuit according to a second variant of the second embodiment, a VC0 24c generates 3-phase clocks having phases shifted from each other by approximately 120 degrees, that is, a first clock VC0, a second clock VC120 and a third clock VC240 as shown in FIG. 19. Assuming that the first clock VC0 is set to be a reference (zero degree), the phases of the second clock VC120 and the third clock VC240 are approximately 120 degrees and 240 degrees, respectively. Each of the first to third clocks VC0 to VC240 has an amplitude which is smaller than a source voltage.

A correcting circuit 25d corrects a propagation delay of each of first to third clocks VC0 to VC240 generated by the VC0. 24c and outputs first to third output clocks CK0 to CK240 when amplifying the first to third clocks VC0 to VC240 to have a source voltage corresponding to electric potentials of first to third control signals DCCO to DCC240 for correcting a difference in a phase among the first to third clocks VC0 to VC240.

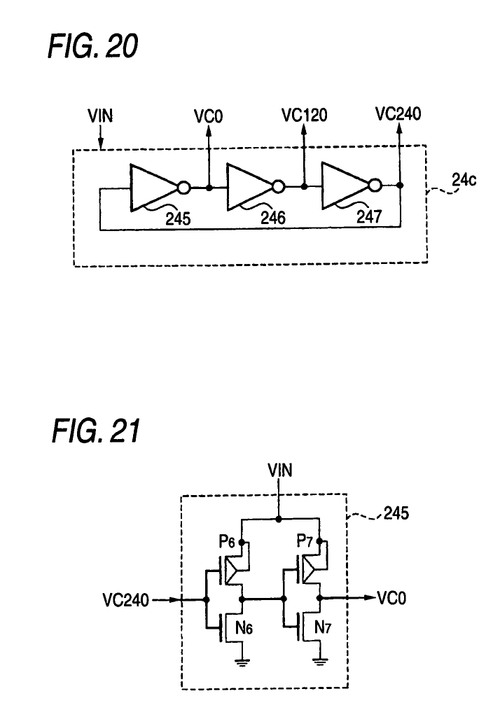

Moreover, the VC0 24c includes first to third inverters 245 to 247 connected like a loop as shown in FIG. 20. The first inverter 245 generates the first clock VC0 from the third clock VC240. The second inverter 246 generates the second clock VC120 from the first clock VC0. The third inverter 247 generates the third clock VC240 from the second clock VC120.

In detail, the first inverter 245 includes a CMOS inverter constituted by a pMOS transistor P₆ and an nMOS transistor N₆, and a CMOS inverter constituted by a pMOS transistor P₇ and an nMOS transistor N₇ as shown in FIG. 21.

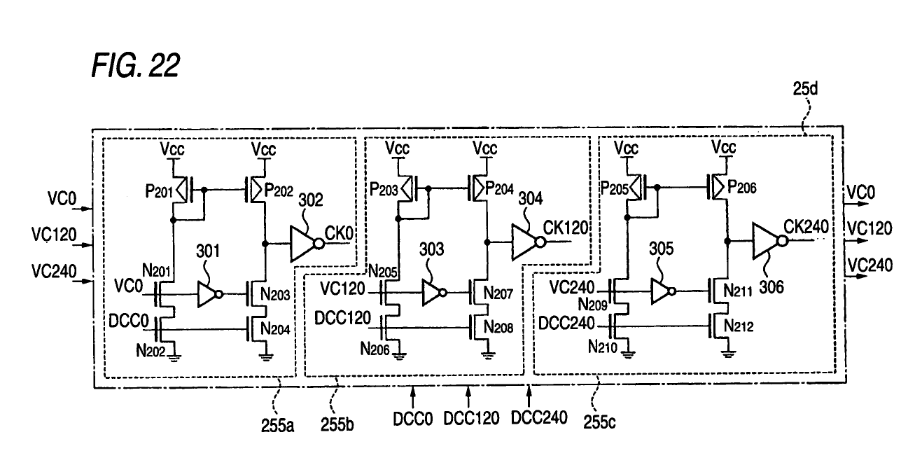

Furthermore, the correcting circuit 25d includes first to third phase correcting circuits 255a to 255c as shown in FIG. 22. The first phase correcting circuit 255a corrects the first clock VC0 in response to the first control signal DCC0 and outputs the first output clock CK0. The second phase correcting circuit 255b corrects the second clock VC120 in response to the second control signal DCC120 and outputs the second output clock CK120. The third phase correcting circuit 255c corrects the third clock VC240 in response to the third control signal DCC240 and outputs the third output clock CK240.

The first phase correcting circuit 255a includes first and second pMOS transistors P₂₀₁ and P₂₀₂, first to fourth nMOS transistors N₂₀₁ to N₂₀₄, and first and second inverters 301 and 302. The second phase correcting circuit 255b includes third and fourth pMOS transistors P₂₀₃ and P₂₀₄, fifth to eighth nMOS transistors N₂₀₅ to N₂₀₈, and third and fourth inverters 303 and 304. The third phase correcting circuit 255c includes fifth and sixth pMOS transistors P₂₀₅ and P₂₀₆, ninth to twelfth nMOS transistors N₂₀₉ to N₂₁₂, and fifth and sixth inverters 305 and 306.

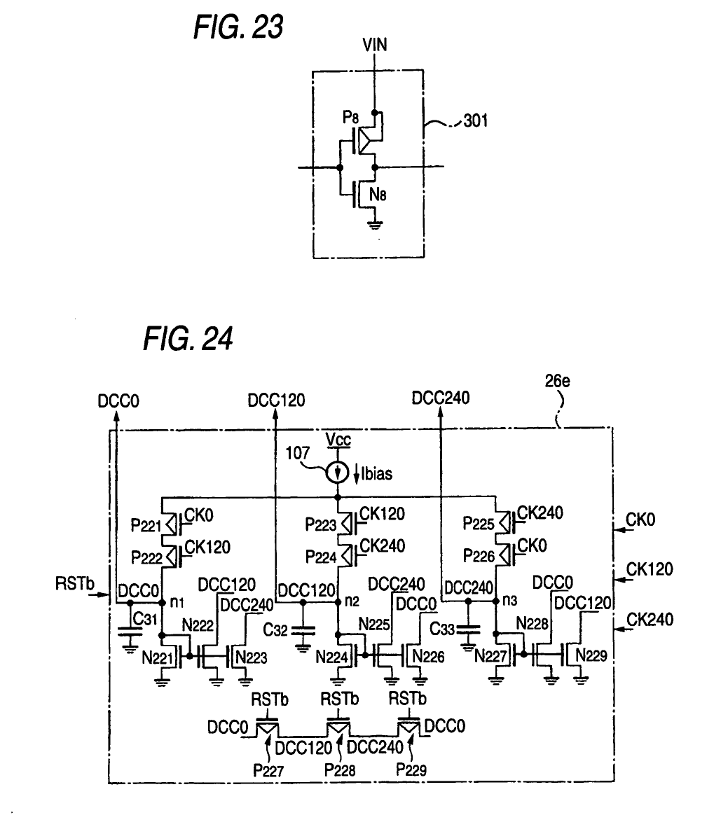

The first inverter 301 is constituted as a CMOS inverter including a pMOS transistor P₈ and an nMOS transistor N₈ as shown in FIG. 23. An input voltage VIN is applied to a source of the pMOS transistor P₈.

Furthermore, a control circuit 26e includes a constant current source 107, first to sixth pMOS transistors P₂₂₁ to P₂₂₆, first to ninth nMOS transistors N₂₂₁ to N₂₂₉, and first to third capacitors C₃₁ to C₃₃ as shown in FIG. 24.

The first and second pMOS transistors P₉₁ and P₉₂ are connected in series between the constant current source 106 and an output node n₁ of the first control signal DCC0. The third and fourth pMOS transistors P₉₃ and P₉₄ are connected in series between the constant current source 106 and an output node n₂ of the fourth control signal DCC180. The fifth and sixth pMOS transistors P₉₅ and P₉₆ are connected in series between the constant current source 106 and an output node n₃ of the second control signal DCC60.

The first and second output clocks CK0 and CK120 are input to gates of the first and second PMOS transistors P₂₂₁ and P₂₂₂, respectively. The second and third output clocks CK120 and CK240 are input to gates of the third and fourth pMOS transistors P₂₂₃ and P₂₂₄, respectively. The third and first output clocks CK240 and CK0 are input to gates of the fifth and sixth pMOS transistors P₂₂₅ and P₂₂₆, respectively.

Furthermore, the first to third nMOS transistors N₂₂₁ to N₂₂₃, the fourth to sixth nMOS transistors N₂₂₄ to N₂₂₆, and the seventh to ninth nMOS transistors N₂₂₇ to N₂₂₉ constitute current mirror circuits, respectively. Drains of the sixth and eighth nMOS transistors N₂₂₆ and N₂₂₈ are connected to the node n₁, a part of signal wirings being omitted. Drains of the second and ninth nMOS transistors N₂₂₂ and N₂₂₉ and those of the third and fifth nMOS transistors N₂₂₃ and N₂₂₅ are connected to the node n₂.

Moreover, the seventh to ninth pMOS transistors P₂₂₇ to P₂₂₉ are set in a conduction state in an initial condition, and the electric potentials of the first to third control signals DCC0 to DCC240 are reset to be equipotential.

By a changeover to a transition condition from the initial condition, the seventh to ninth pMOS transistors P₂₂₇ to P₂₂₉ are brought into a non-conduction state. In the case in which an error is made over a difference in a phase among the first to third output clocks CK0 to CK240, a difference in an electric potential is made over the first to third control signals DCC0 to DCC240.

According to the second variant of the second embodiment, thus, it is possible to feedback a difference in a phase between the first to third output clocks CK0 to CK240 and to set the difference in a phase between the clocks to be equal to 120 degrees. Accordingly, it is possible to generate the 3-phase output clocks CK0 to CK240 having phases shifted accurately from each other by 120 degrees without using a clock having a higher frequency than these clocks. Furthermore, it is possible to provide the semiconductor integrated circuit capable of increasing a transfer speed of output data SROUT to be three times as high as the frequencies of the first to third output clocks CK0 to CK240 while suppressing an increase in a clock frequency and a consumed power.

According to the above-embodiments, it is possible to provide a semiconductor integrated circuit capable of generating a multiphase high-frequency clock having a phase shifted evenly.

### Other Embodiments

While the invention has been described above based on the first and second embodiments, it is to be understood that the statement and drawings constituting a part of the disclosure do not restrict the invention. From the disclosure, various alternative embodiments, examples and application techniques are apparent to the skilled in the art.

Although the description has been given to an example in which the VCOs 24a to 24c, the correcting circuits 25a to 25d and the control circuits 26a to 26e are applied to the PLL circuit in the first and second embodiments, the PLL circuit is not restricted but they can be applied to any circuit for generating a multiphase high-frequency clock, for example, a DLL circuit.

In the second embodiment, the first variant of the second embodiment and the second variant of the second embodiment, moreover, the description has been given to an example in which the 4-phase clocks, the 6-phase clocks and the 3-phase clocks are used. However, it is possible to use the invention to whole multiphase clocks such as 5-phase, 7-phase and 8-phase clocks in addition to the 4-phase, 6-phase and 3-phase clocks.

While the description has been given to an example in which each circuit is constituted by the MOS transistor in the first and second embodiments, it is also possible to utilize a material other than a silicon oxide film (an SiO₂ film) as a gate insulating film. More specifically, the circuit is not restricted to the metal-oxide film—semiconductor (MOS) transistor but it is sufficient that a metal-insulating film—semiconductor (MIS) transistor is used.

Thus, it is to be understood that the invention includes various embodiments which have not been described. Accordingly, the invention is restricted by only inventive specific matters in proper claims based on the disclosure.

What is claimed is:

1. A semiconductor integrated circuit comprising:
a multiphase clock generating circuit that generates, in response to an input voltage, a first pair of clocks having reverse phases to each other and a second pair of clocks having phases which are substantially orthogonal to the phases of the first pair of clocks;
a correcting circuit that generates first and second output clock pairs by correcting a phase difference of the first and second clock pairs and duty cycles of the first and second clock pairs and a difference in phase between the first and second clock pairs; and
a control circuit that controls the correcting circuit by detecting duty cycles of the first and second output clock pairs and a difference in phase between the first and second output clock pairs.

2. The semiconductor integrated circuit according to claim 1, wherein a mismatch of transistor characteristics in the correcting circuits parasitic capacitor of transistor, and parasitic resistance of the transistor cause the phase difference of the first and second output clock pairs.

3. The semiconductor integrated circuit according to claim 1, wherein the correcting circuit generates the first and second output clock pairs of which the duty cycles are 50%.

4. The semiconductor integrated circuit according to claim 1, wherein the control circuit includes:
a first duty cycle detecting circuit converting a difference in the duty cycle between output clocks in the first output clock pair into a first current difference and integrating the first current difference to generate a first control signal pair;
a second duty cycle detecting circuit converting a difference in the duty cycle between output clocks in the second output clock pair into a second current difference and integrating the second current difference to generate a second control signal pair; and
a phase difference detecting circuit converting a difference in a phase between the first and second output clock pairs into a third current difference and integrating the third current difference to generate a phase difference control signal pair,
wherein the correcting circuit corrects the duty cycle of the first output clock pair corresponding to a difference in an electric potential of the first control signal pair,
wherein the correcting circuit corrects the duty cycle of the second output clock pair corresponding to a difference in an electric potential of the second control signal pair, and
wherein the correcting circuit corrects a difference in a phase between the first and second clock pairs corresponding to the phase difference control signal pair.

5. The semiconductor integrated circuit according to claim 4, wherein the correcting circuit generates the first and second output clock pairs of which the duty cycles are 50%.

6. The semiconductor integrated circuit according to claim 4, wherein a rising and falling edges of the first pair of clocks are corrected based on the phase difference control signal pair so as to generate the first output clock pair.

7. The semiconductor integrated circuit according to claim 4, wherein the first duty cycle detecting circuit increases a difference in an electric potential between the first control signal pair when the duty cycle of the first output clock pair are shifted from 50%.

8. The semiconductor integrated circuit according to claim 1, wherein the control circuit includes:
a first duty cycle detecting circuit converting a difference in a phase between output clocks in the first output clock pair into a first current difference and integrating the first current difference to generate a first control signal pair;
a second duty cycle detecting circuit converting a difference in a phase between output clocks in the second output clock pair into a second current difference and integrating the second current difference to generate a second control signal pair; and
a phase difference detecting circuit detecting the difference in the phase between the first and second output clock pairs and controlling respective mean electric potentials of the first and second control signal pairs corresponding to the difference in the phase between the first and second output clock pairs,
wherein the correcting circuit corrects the duty cycle of the first clock pair corresponding to a difference in an electric potential of the first control signal pair,
wherein the correcting circuit corrects the duty cycle of the second clock pair corresponding to a difference in an electric potential of the second control signal pair, and
wherein the correcting circuit corrects a difference in a phase between the first and second clock pairs corresponding to the respective mean electric potentials of the first and second control signal pairs.

9. The semiconductor integrated circuit according to claim 8, wherein the correcting circuit generates the first and second output clock pairs of which the duty cycles are 50%.

10. The semiconductor integrated circuit according to claim 8, wherein the first duty cycle detecting circuit increases a difference in an electric potential between the first control signal pair when the duty cycle of the first output clock pair are shifted from 50%.

11. The semiconductor integrated circuit according to claim 8, wherein positions of both of rising and falling edges of the first output clock pair are corrected based on the mean electric potential of the first control signal pair, and
wherein positions of both of rising and falling edges of the second output clock pair are corrected based on the mean electric potential of the second control signal pair.

12. A semiconductor integrated circuit comprising:
a multiphase clock generating circuit generating multiphase clocks including at least three clocks having different phases from each other in response to an input voltage;
a correcting circuit correcting a difference in a phase between the clocks of the multiphase clocks and outputting multiphase output clocks including the same number of output clocks as the clocks in the multiphase clocks; and
a control circuit detecting a difference in a phase between the output clocks having adjacent phases to each other in the multiphase output clocks and controlling the correcting circuit.

13. The semiconductor integrated circuit according to claim 12, wherein the multiphase clock generating circuit generates, as the multiphase clocks, a first pair of clocks having reverse phases to each other and a second pair of clocks having phases which are substantially orthogonal to phases of the first pair of clocks,
wherein the control circuit receives first to fourth output clocks output from the correcting circuit,
wherein the control circuit generates a first control signal pair having a difference in an electric potential corresponding to a difference in a phase between the fourth and first output clocks and a difference in a phase between the second and third output clocks,
wherein the control circuit generates a second control signal pair having a difference in an electric potential corresponding to a difference in a phase between the first and second output clocks and a difference in a phase between the third and fourth output clocks,
wherein the correcting circuit corrects a difference in a phase between clocks in the first clock pair corresponding to the difference in the electric potential of the first control signal pair,
wherein the correcting circuit corrects a difference in a phase between clocks in the second clock pair corresponding to the difference in the electric potential of the second control signal pair, and
wherein the correcting circuit corrects the difference in the phase between the first and second clock pairs corresponding to respective mean electric potentials of the first and second control signal pairs.

14. The semiconductor integrated circuit according to claim 13, wherein positions of both of rising and falling edges of the first output clock pair are corrected based on the mean electric potential of the first control signal pair, and
wherein positions of both of rising and falling edges of the second output clock pair are corrected based on the mean electric potential of the second control signal pair.

15. A correcting method of semiconductor integrated circuit, comprising:
generating, in response to an input voltage, a first pair of clocks having reverse phases to each other and a second pair of clocks having phases which are substantially orthogonal to the phases of the first pair of clocks;
generating first and second output clock pairs by correcting a phase difference of the first and second clock pairs and duty cycles of the first and second clock pairs and a difference in phase between the first and second clock pairs; and
detecting duty cycles of the first and second output clock pairs and a difference in phase between the first and second output clock pairs.

16. The correcting method of semiconductor integrated circuit according to claim 15, wherein a mismatch of transistor characteristics causes the phase difference of the first and second output clock pairs.

17. The correcting method of semiconductor integrated circuit according to claim 15, wherein the duty cycles of the first and second output clock pairs are 50%.
